(19) United States
(12) Patent Application Publication
(10) Pub. No.: US 2015/0349128 A1
(43) Pub. Date: Dec. 3, 2015

(54) SEMICONDUCTOR DEVICE AND METHOD FOR MANUFACTURING THE SAME

(71) Applicant: Semiconductor Energy Laboratory Co., Ltd., Atsugi-shi (JP)

(72) Inventor: Hidekazu MIYAIRI, Hadano (JP)

(21) Appl. No.: 14/719,757

(22) Filed: May 22, 2015

(30) Foreign Application Priority Data
May 27, 2014 (JP) 2014-108709

(51) Int. Cl. H01L 29/786; H01L 29/66; H01L 21/02

(52) U.S. Cl. CPC H01L 29/7869; H01L 21/02565; H01L 21/02664; H01L 29/66969

(57) ABSTRACT

A semiconductor device including an insulator, a first conductor as a source electrode, a second conductor as a drain electrode, a third conductor as a gate electrode, and an island-shaped semiconductor is provided. The first conductor includes a first side surface, a second side surface, and a third side surface. The second conductor includes a fourth side surface. The first conductor and the second conductor are positioned to make the first side surface and the fourth side surface face each other. The first conductor includes a first corner portion between the first side surface and the second side surface and a second corner portion between the second side surface and the third side surface. The first corner portion includes a portion having a smaller radius of curvature than the second corner portion.

### TECHNICAL FIELD

The present invention relates to a transistor and a semiconductor device, and a manufacturing method thereof, for example. The present invention relates to a display device, a light-emitting device, a lighting device, a power storage device, a memory device, a processor, or an electronic device, for example. The present invention relates to a method for manufacturing a display device, a liquid crystal display device, a light-emitting device, a memory device, or an electronic device. The present invention relates to a driving method of a semiconductor device, a display device, a liquid crystal display device, a light-emitting device, a memory device, or an electronic device.

Note that one embodiment of the present invention is not limited to the above technical field. The technical field of one embodiment of the invention disclosed in this specification and the like relates to an object, a method, or a manufacturing method. In addition, one embodiment of the present invention relates to a process, a machine, manufacture, or a composition of matter.

In this specification and the like, a semiconductor device generally means a device that can function by utilizing semiconductor characteristics. A display device, a light-emitting device, a lighting device, an electro-optical device, a semiconductor circuit, and an electronic device include a semiconductor device in some cases.

### BACKGROUND ART

A technique for forming a transistor by using a semiconductor over a substrate having an insulating surface has attracted attention. The transistor is applied to a wide range of semiconductor devices such as an integrated circuit and a display device. Silicon is known as a semiconductor applicable to a transistor.

As silicon which is used as a semiconductor of a transistor, either amorphous silicon or polycrystalline silicon is used depending on the purpose. For example, in the case of a transistor included in a large display device, it is preferable to use amorphous silicon, which can be used to form a film on a large substrate with the established technique. On the other hand, in the case of a transistor included in a high-performance display device where a driver circuit and a pixel circuit are formed over the same substrate, it is preferable to use polycrystalline silicon, which can be used to form a transistor having a high field-effect mobility. As a method for forming polycrystalline silicon, high-temperature heat treatment or laser light treatment which is performed on amorphous silicon has been known.

Recently, a transistor which includes an amorphous oxide semiconductor and a transistor which includes an amorphous oxide semiconductor containing a microcrystal have been disclosed (see Patent Document 1). An oxide semiconductor can be deposited by a sputtering method or the like, and thus can be used for a semiconductor of a transistor in a large display device. Because a transistor including an oxide semiconductor has high field-effect mobility, a high-performance display device in which, for example, a driver circuit and a pixel circuit are formed over the same substrate can be obtained. In addition, there is an advantage that capital investment can be reduced because part of production equipment for a transistor including amorphous silicon can be retrofitted and utilized.

In 2014, it was reported that a transistor including a crystalline In—Ga—Zn oxide has more excellent electrical characteristics and higher reliability than a transistor including an amorphous In—Ga—Zn oxide (see Non-Patent Document 1). Non-Patent Document 1 reports that a crystal boundary is not clearly observed in an In—Ga—Zn oxide including a c-axis aligned crystalline oxide semiconductor (CAAC-OS).

It is known that a transistor including an oxide semiconductor has an extremely low leakage current in a non-conductive state. For example, a low power consumption CPU and the like utilizing a characteristic of a low leakage current of the transistor including an oxide semiconductor are disclosed (see Patent Document 2). Patent Document 3 discloses that a transistor having high field-effect mobility can be obtained by a well potential formed using an active layer formed of oxide semiconductors.

### REFERENCE

### Patent Document

[Patent Document 1] Japanese Published Patent Application No. 2006-165528
[Patent Document 2] Japanese Published Patent Application No. 2012-257187
[Patent Document 3] Japanese Published Patent Application No. 2012-59860

### Non-Patent Document

[Non-Patent Document 1] S. Yamazaki, H. Suzawa, K. Inoue, K. Kato, T. Hirohashi, K. Okazaki, and N. Kimizuka, Japanese Journal of Applied Physics, Vol. 53, 2014, 04ED18

### DISCLOSURE OF INVENTION

An object is to provide a semiconductor device with excellent electrical characteristics. Another object is to provide a semiconductor device with stable electrical characteristics. Another object is to provide a semiconductor device with small variations in electrical characteristics. Another object is to provide a highly integrated semiconductor device. Another object is to provide a module including the semiconductor device. Another object is to provide an electronic device including the semiconductor device or the module.

Another object is to provide a novel semiconductor device. Another object is to provide a novel module. Another object is to provide a novel electronic device.

Note that the descriptions of these objects do not disturb the existence of other objects. In one embodiment of the present invention, there is no need to achieve all the objects. Other objects will be apparent from and can be derived from the description of the specification, the drawings, the claims, and the like.

(1) One embodiment of the present invention is a semiconductor device including an insulator, a first conductor, a second conductor, a third conductor, and an island-shaped semiconductor. The first conductor includes a region in contact with a top surface of the semiconductor. The first conductor does not include a region in contact with a side surface of the semiconductor. The second conductor includes a region in contact with the top surface of the semiconductor. The second conductor does not include a region in contact with the side surface of the semiconductor. The third conductor includes a region in which the semiconductor and the third conductor overlap with each other with the insulator positioned therebetween. The first conductor includes a first side surface, a second side surface, and a third side surface. The second conductor includes a fourth side surface. The first conductor and the second conductor are positioned to make the first side surface and the fourth side surface face each other. The first conductor includes a first corner portion between the first side surface and the second side surface and a second corner portion between the second side surface and the third side surface. The first corner portion includes a portion having a smaller radius of curvature than the second corner portion.

(2) One embodiment of the present invention is a semiconductor device including a first insulator, a second insulator, a first conductor, a second conductor, a third conductor, a fourth conductor, and a semiconductor. The semiconductor includes a region in contact with a top surface of the first insulator. The first conductor includes a region in contact with a top surface of the semiconductor. The second conductor includes a region in contact with the top surface of the semiconductor. The second insulator includes a region in contact with the top surface of the semiconductor. The third conductor includes a region in which the semiconductor and the third conductor overlap with each other with the second insulator positioned therebetween. An opening reaching the fourth conductor is provided in the semiconductor and the first insulator. The first conductor includes a region in contact with the fourth conductor through the opening.

(3) One embodiment of the present invention is the semiconductor device described in (1) or (2) where the semiconductor includes a region in which a length in the short-side direction is more than or equal to 5 nm and less than or equal to 300 nm.

(4) One embodiment of the present invention is the semiconductor device described in any one of (1) to (3) where the semiconductor is an oxide including indium, an element M (the element M is one of aluminum, gallium, yttrium, and tin), and zinc.

(5) One embodiment of the present invention is the semiconductor device described in any one of (1) to (4) where the semiconductor includes a first semiconductor and a second semiconductor, and the first semiconductor has higher electron affinity than the second semiconductor.

(6) One embodiment of the present invention is a method for manufacturing a semiconductor device that includes a step of depositing a first semiconductor, a step of depositing a first conductor over the first semiconductor, a step of etching a portion of the first conductor to form a second conductor and to expose a portion of the first semiconductor, a step of forming a resist over a portion of the second conductor and the exposed portion of the first semiconductor, a step of etching the second conductor with the resist used as a mask to form a third conductor and a fourth conductor, and a step of etching the first semiconductor with the resist, the third conductor, and the fourth conductor used as masks to form a second semiconductor.

(7) One embodiment of the present invention is the method for manufacturing the semiconductor device described in (6) where the second semiconductor includes a region in which a length in the short-side direction is more than or equal to 5 nm and less than or equal to 300 nm.

(8) One embodiment of the present invention is a method for manufacturing a semiconductor device that includes a step of depositing a first semiconductor, a step of etching a portion of the first semiconductor to form a second semiconductor, a step of depositing a first conductor over the second semiconductor, a step of etching a portion of the first conductor to form a second conductor and to expose a portion of the second semiconductor, a step of forming a resist over a portion of the second conductor and the exposed portion of the second semiconductor, a step of etching the second conductor with the resist used as a mask to form a third conductor and a fourth conductor, and a step of etching the second semiconductor with the resist, the third conductor, and the fourth conductor used as masks to form a third semiconductor.

(9) One embodiment of the present invention is the method for manufacturing the semiconductor device described in (8) where the third semiconductor includes a region in which a length in the short-side direction is more than or equal to 5 nm and less than or equal to 300 nm.

(10) One embodiment of the present invention is the method for manufacturing the semiconductor device described in any one of (6) to (9) where the first semiconductor is an oxide including indium, an element M (the element M is one of aluminum, gallium, yttrium, and tin), and zinc.

A semiconductor device with excellent electrical characteristics can be provided. A semiconductor device with stable electrical characteristics can be provided. A semiconductor device with small variations in electrical characteristics can be provided. A highly integrated semiconductor device can be provided. A module including the semiconductor device can be provided. An electronic device including the semiconductor device or the module can be provided.

A novel semiconductor device can be provided. A novel module can be provided. A novel electronic device can be provided.

Note that the description of these effects does not disturb the existence of other effects. In one embodiment of the present invention, there is no need to obtain all the above effects. Other effects will be apparent from and can be derived from the description of the specification, the drawings, the claims, and the like.

### BRIEF DESCRIPTION OF DRAWINGS

FIGS. 1A and 1B are a top view and a cross-sectional view illustrating a method for manufacturing a transistor.

FIGS. 2A and 2B are a top view and a cross-sectional view illustrating a method for manufacturing a transistor.

FIGS. 3A and 3B are a top view and a cross-sectional view illustrating a method for manufacturing a transistor.

FIGS. 4A and 4B are a top view and a cross-sectional view illustrating a method for manufacturing a transistor.

FIGS. 5A and 5B are a top view and a cross-sectional view illustrating a method for manufacturing a transistor.

FIGS. 6A and 6B are a top view and a cross-sectional view illustrating a method for manufacturing a transistor.

FIGS. 7A and 7B are a top view and a cross-sectional view illustrating a method for manufacturing a transistor.

FIGS. 8A and 8B are a top view and a cross-sectional view illustrating a method for manufacturing a transistor.

FIGS. 9A and 9B are a top view and a cross-sectional view illustrating a method for manufacturing a transistor.

FIGS. 10A and 10B are a top view and a cross-sectional view illustrating a method for manufacturing a transistor.

FIGS. 11A and 11B are a top view and a cross-sectional view of a transistor.

FIGS. 12A and 12B are a top view and a cross-sectional view of a transistor.

FIGS. 13A and 13B are a cross-sectional view and a band diagram of a transistor.

FIGS. 14A and 14B are each a circuit diagram of a semiconductor device.

FIG. 15 is a cross-sectional view of a semiconductor device.

FIG. 16 is a cross-sectional view of a semiconductor device.

FIG. 17 is a cross-sectional view of a semiconductor device.

FIG. 18 is a cross-sectional view of a semiconductor device.

FIG. 19 is a cross-sectional view of a semiconductor device.

FIG. 20 is a cross-sectional view of a semiconductor device.

FIGS. 21A and 21B are each a circuit diagram of a memory device.

FIG. 22 is a cross-sectional view of a semiconductor device.

FIG. 23 is a cross-sectional view of a semiconductor device.

FIG. 24 is a cross-sectional view of a semiconductor device.

FIG. 25 is a cross-sectional view of a semiconductor device.

FIG. 26 is a cross-sectional view of a semiconductor device.

FIG. 27 is a cross-sectional view of a semiconductor device.

FIG. 28 is a block diagram illustrating a CPU.

FIG. 29 is a circuit diagram of a memory element.

FIGS. 30A to 30C are a top view and circuit diagrams of a display device.

FIGS. 31A to 31F each illustrate an electronic device.

FIGS. 32A to 32D are Cs-corrected high-resolution TEM images of a cross section of a CAAC-OS and a schematic cross-sectional view of the CAAC-OS.

FIGS. 33A to 33D are Cs-corrected high-resolution TEM images of a plane of a CAAC-OS.

FIGS. 34A to 34C show structural analysis of a CAAC-OS and a single crystal oxide semiconductor by XRD.

FIGS. 35A and 35B show electron diffraction patterns of a CAAC-OS.

FIG. 36 shows a change in crystal part of an In—Ga—Zn oxide induced by electron irradiation.

### BEST MODE FOR CARRYING OUT THE INVENTION

Hereinafter, embodiments of the present invention will be described in detail with the reference to the drawings. However, the present invention is not limited to the description below, and it is easily understood by those skilled in the art that embodiments and details disclosed herein can be modified in various ways. Further, the present invention is not construed as being limited to description of the embodiments. In describing structures of the present invention with reference to the drawings, common reference numerals are used for the same portions in different drawings. Note that the same hatched pattern is applied to similar parts, and the similar parts are not especially denoted by reference numerals in some cases.

Note that the size, the thickness of films (layers), or the region in drawings is sometimes exaggerated for clarity.

In this specification, the terms “film” and “layer” can be interchanged with each other.

A portion between two side surfaces that has a curved surface is called “a corner portion.” In the case where a portion between two side surfaces has a curved surface, the two side surfaces can also be expressed as one curved surface.

A voltage refers to a potential difference between a certain potential and a reference potential (e.g., a ground potential (GND) or a source potential) in many cases. A voltage can be referred to as a potential and vice versa.

Note that the ordinal numbers such as “first” and “second” in this specification are used for convenience and do not denote the order of steps or the stacking order of layers. Therefore, for example, the term “first” can be replaced with the term “second,” “third,” or the like as appropriate. In addition, the ordinal numbers in this specification and the like are not necessarily the same as those which specify one embodiment of the present invention.

Note that a “semiconductor” includes characteristics of an “insulator” in some cases when the conductivity is sufficiently low, for example. Further, a “semiconductor” and an “insulator” cannot be strictly distinguished from each other in some cases because a border between the “semiconductor” and the “insulator” is not clear. Accordingly, a “semiconductor” in this specification can be called an “insulator” in some cases. Similarly, an “insulator” in this specification can be called a “semiconductor” in some cases.

Further, a “semiconductor” includes characteristics of a “conductor” in some cases when the conductivity is sufficiently high, for example. Further, a “semiconductor” and a “conductor” cannot be strictly distinguished from each other in some cases because a border between the “semiconductor” and the “conductor” is not clear. Accordingly, a “semiconductor” in this specification can be called a “conductor” in some cases. Similarly, a “conductor” in this specification can be called a “semiconductor” in some cases.

Note that an impurity in a semiconductor refers to, for example, elements other than the main components of the semiconductor. For example, an element with a concentration of lower than 0.1 atomic % is an impurity. When an impurity is contained, density of states (DOS) may be formed in the semiconductor, the carrier mobility may be decreased, or the crystallinity may be lowered, for example. In the case where the semiconductor is an oxide semiconductor, examples of an impurity which changes characteristics of the semiconductor include Group 1 elements, Group 2 elements, Group 14 elements, Group 15 elements, and transition metals other than the main components; specifically, there are hydrogen (included in water), lithium, sodium, silicon, boron, phosphorus, carbon, and nitrogen, for example. In the case of an oxide semiconductor, oxygen vacancy may be formed by entry of impurities such as hydrogen.

Further, in the case where the semiconductor is silicon, examples of an impurity which changes characteristics of the semiconductor include oxygen, Group 1 elements except hydrogen, Group 2 elements, Group 13 elements, and Group 15 elements.

In this specification, the phrase “A has a region with a concentration B” includes, for example, “the concentration of the entire region in a region of A in the depth direction is B,” “the average concentration in a region of A in the depth direction is B,” “the median value of a concentration in a region of A in the depth direction is B,” “the maximum value of a concentration in a region of A in the depth direction is B,” “the minimum value of a concentration in a region of A in the depth direction is B,” “a convergence value of a concentration in a region of A in the depth direction is B,” and “a concentration in a region of A in which a probable value is obtained in measurement is B.”

In this specification, the phrase “A has a region with a size B, a length B, a thickness B, a width B, or a distance B” includes, for example, “the size, the length, the thickness, the width, or the distance of the entire region in a region of A is B,” “the average value of the size, the length, the thickness, the width, or the distance of a region of A is B,” “the median value of the size, the length, the thickness, the width, or the distance of a region of A is B,” “the maximum value of the size, the length, the thickness, the width, or the distance of a region of A is B,” “the minimum value of the size, the length, the thickness, the width, or the distance of a region of A is B,” “a convergence value of the size, the length, the thickness, the width, or the distance of a region of A is B,” and “the size, the length, the thickness, the width, or the distance of a region of A in which a probable value is obtained in measurement is B.”

Note that the channel length refers to, for example, a distance between a source (a source region or a source electrode) and a drain (a drain region or a drain electrode) in a region where a semiconductor (or a portion where a current flows in a semiconductor when a transistor is on) and a gate electrode overlap with each other or a region where a channel is formed in a top view of the transistor. In one transistor, channel lengths in all regions do not necessarily have the same value. In other words, the channel length of one transistor is not fixed to one value in some cases. Therefore, in this specification, the channel length is any one of values, the maximum value, the minimum value, or the average value in a region where a channel is formed.

The channel width refers to, for example, the length of a portion where a source and a drain face each other in a region where a semiconductor (or a portion where a current flows in a semiconductor when a transistor is on) and a gate electrode overlap with each other, or a region where a channel is formed. In one transistor, channel widths in all regions do not necessarily have the same value. In other words, a channel width of one transistor is not fixed to one value in some cases. Therefore, in this specification, a channel width is any one of values, the maximum value, the minimum value, or the average value in a region where a channel is formed.

Note that depending on a transistor structure, a channel width in a region where a channel is formed actually (hereinafter referred to as an effective channel width) is different from a channel width shown in a top view of a transistor (hereinafter referred to as an apparent channel width) in some cases. For example, in a transistor having a three-dimensional structure, an effective channel width is greater than an apparent channel width shown in a top view of the transistor, and its influence cannot be ignored in some cases. For example, in a miniaturized transistor having a three-dimensional structure, the proportion of a channel region formed in a side surface of a semiconductor is higher than the proportion of a channel region formed in a top surface of a semiconductor in some cases. In that case, an effective channel width obtained when a channel is actually formed is greater than an apparent channel width shown in the top view.

In a transistor having a three-dimensional structure, an effective channel width is difficult to measure in some cases. For example, to estimate an effective channel width from a design value, it is necessary to assume that the shape of a semiconductor is known as an assumption condition. Therefore, in the case where the shape of a semiconductor is not known accurately, it is difficult to measure an effective channel width accurately.

Therefore, in this specification, in a top view of a transistor, an apparent channel width that is a length of a portion where a source and a drain face each other in a region where a semiconductor and a gate electrode overlap with each other is referred to as a surrounded channel width (SCW) in some cases. Further, in this specification, in the case where the term “channel width” is simply used, it may denote a surrounded channel width and an apparent channel width. Alternatively, in this specification, in the case where the term “channel width” is simply used, it may denote an effective channel width in some cases. Note that the values of a channel length, a channel width, an effective channel width, an apparent channel width, a surrounded channel width, and the like can be determined by obtaining and analyzing a cross-sectional TEM image and the like.

Note that in the case where field-effect mobility, a current value per channel width, and the like of a transistor are obtained by calculation, a surrounded channel width may be used for the calculation. In that case, a value different from one in the case where an effective channel width is used for the calculation is obtained in some cases.

Note that in this specification, the description “A has a shape such that an end portion extends beyond an end portion of B” may indicate, for example, the case where at least one of end portions of A is positioned on an outer side than at least one of end portions of B in a top view or a cross-sectional view. Thus, the description “A has a shape such that an end portion extends beyond an end portion of B” can be alternatively referred to as the description “one of end portions of A is positioned on an outer side than one of end portions of B.”

In this specification, the term “parallel” indicates that the angle formed between two straight lines is greater than or equal to −10° and less than or equal to 10°, and accordingly also includes the case where the angle is greater than or equal to −5° and less than or equal to 5°. A term “substantially parallel” indicates that the angle formed between two straight lines is greater than or equal to −30° and less than or equal to 30°. The term “perpendicular” indicates that the angle formed between two straight lines is greater than or equal to 80° and less than or equal to 100°, and accordingly includes the case where the angle is greater than or equal to 85° and less than or equal to 95°. A term “substantially perpendicular” indicates that the angle formed between two straight lines is greater than or equal to 60° and less than or equal to 120°.

In this specification, the trigonal and rhombohedral crystal systems are included in the hexagonal crystal system.

### <Transistor>

The transistors of embodiments of the present invention will be described below.

Here, an example of a method for forming a resist used in manufacture of the transistor in one embodiment of the present invention is described. First, a layer of a photosensitive organic or inorganic substance is formed by a spin coating method or the like. Then, the layer of the photosensitive organic or inorganic substance is irradiated with light with the use of a photomask. As such light, KrF excimer laser light, ArF excimer laser light, extreme ultraviolet (EUV) light, or the like may be used. Alternatively, a liquid immersion technique may be employed in which a portion between a substrate and a projection lens is filled with liquid (e.g., water) to perform light exposure. The layer of the photosensitive organic or inorganic substance may be irradiated with an electron beam or an ion beam instead of the above light. Note that a photomask is not necessary in the case of using an electron beam or an ion beam. After that, a region of the layer of the photosensitive organic or inorganic substance that has been exposed to light is removed or left with the use of a developer, so that the resist is formed.

Note that in this specification, a simple phrase “a resist is formed” includes the case where an anti-reflection layer (bottom anti-reflective coating (BARC)) is formed under a resist. When BARC is used, first, the BARC is etched using a resist, and then, with the use of the resist and the BARC, an object to be processed is etched. Note that in some cases, an organic or inorganic substance without a function of an anti-reflection layer may be used instead of BARC.

Removal of a resist described in this specification uses plasma treatment and/or wet etching. Note that as the plasma treatment, plasma ashing can be favorably used. When a resist or the like is removed insufficiently, the remaining resist or the like may be removed using hydrofluoric acid at a concentration of higher than or equal to 0.001 volume % and lower than or equal to 1 volume % and/or ozone water, for example.

### <Reference Example of Method for Manufacturing Transistor>

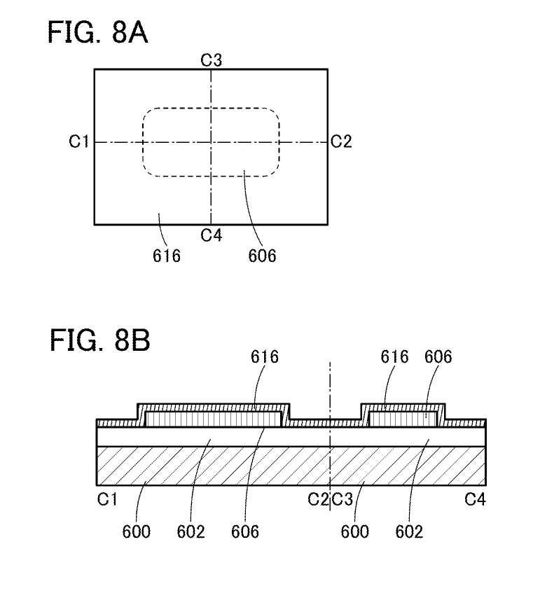

A reference example of a method for manufacturing a transistor is described with reference to FIGS. 8A and 8B, FIGS. 9A and 9B, and FIGS. 10A and 10B.

First, a substrate 600 is prepared. Next, an insulator 602 is deposited. Next, a semiconductor to be a semiconductor 606 is deposited. Next, a resist is formed. Then, the semiconductor to be the semiconductor 606 is etched using the resist as a mask, whereby the island-shaped semiconductor 606 is formed. After that, the resist is removed. Then, a conductor 616 is deposited (see FIGS. 8A and 8B). FIG. 8A is a top view illustrating the method for manufacturing the transistor and FIG. 8B is a cross-sectional view taken along dashed-dotted line C1-C2 and dashed-dotted line C3-C4 in FIG. 8A.

As illustrated in FIG. 8A, a corner portion of the semiconductor 606 has a round shape. That is, a portion between two side surfaces of the semiconductor 606 has a curved surface. For example, it is known that by a photolithography process or the like, a corner portion of a resist has a round shape because of optical proximity even when a photomask has a square-cornered pattern. This effect appears clearly particularly when a minute shape is employed, e.g., when a pattern whose length in the short-side direction is more than or equal to 5 nm and less than or equal to 300 nm, or specifically, more than or equal to 5 nm and less than or equal to 100 nm is formed.

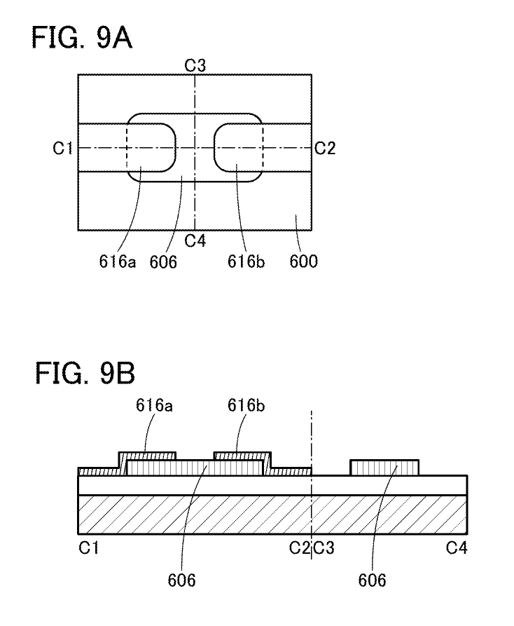

Next, a resist is formed. Then, the conductor 616 is etched using the resist as a mask, whereby a conductor 616a and a conductor 616b are formed. After that, the resist is removed (see FIGS. 9A and 9B). FIG. 9A is a top view illustrating the method for manufacturing the transistor and FIG. 9B is a cross-sectional view taken along dashed-dotted line C1-C2 and dashed-dotted line C3-C4 in FIG. 9A.

As illustrated in FIG. 9A, corner portions of the conductor 616a and the conductor 616b each have a round shape. That is, a portion between two side surfaces of the conductor 616a has a curved surface. Furthermore, a portion between two side surfaces of the conductor 616b has a curved surface.

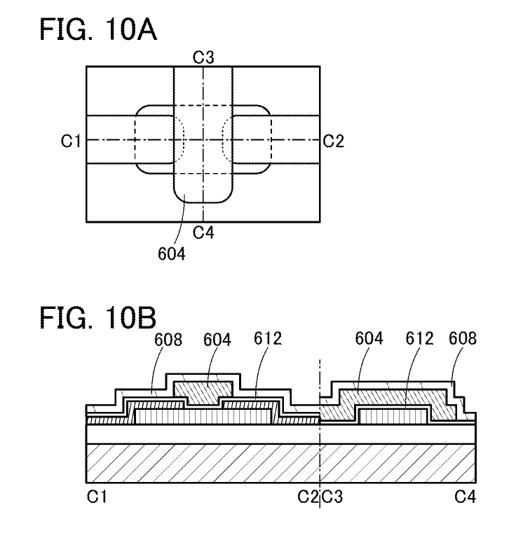

Next, an insulator 612 is deposited. Next, a conductor to be a conductor 604 is deposited. Next, a resist is formed over the conductor to be the conductor 604. Then, the conductor to be the conductor 604 is etched using the resist as a mask, whereby the conductor 604 is formed. After that, the resist is removed. Then, an insulator 608 is deposited. Through the above steps, the transistor can be manufactured (see FIGS. 10A and 10B). FIG. 10A is a top view illustrating the method for manufacturing the transistor and FIG. 10B is a cross-sectional view taken along dashed-dotted line C1-C2 and dashed-dotted line C3-C4 in FIG. 10A.

As illustrated in FIG. 10A, a corner portion of the conductor 604 has a round shape. That is, a portion between two side surfaces of the conductor 604 has a curved surface.

In the transistor manufactured as described above, the conductor 604 has a function of a gate electrode. The insulator 612 has a function of a gate insulator. The conductor 616a and the conductor 616b have functions of a source electrode and a drain electrode. The semiconductor 606 includes a channel formation region.

Note that the transistor does not necessarily include the substrate 600. The transistor does not necessarily include the insulator 602. The transistor does not necessarily include the insulator 608.

In the transistor illustrated in FIGS. 10A and 10B, the corner portions of the conductor 616a and the conductor 616b serving as the source electrode and the drain electrode each have a curved surface. Specifically, each of the conductor 616a and the conductor 616b has a portion with a large radius of curvature at the corner portion on the side where it faces the other. Thus, a channel length of the transistor at the corner portions of the conductor 616a and the conductor 616b is different from a channel length at the other portions. Accordingly, in the channel formation region, the current easily flows in some regions while not in other regions. In other words, the channel width is smaller than designed and on-state current is lower. Moreover, the corner portion is not always formed to have the same shape, which causes variation in electrical characteristics between a plurality of transistors. Note that a radius of curvature of a corner portion means a radius of curvature in a cross section parallel to, for example, a top surface of a substrate.

### <Method 1 for Manufacturing Transistor>

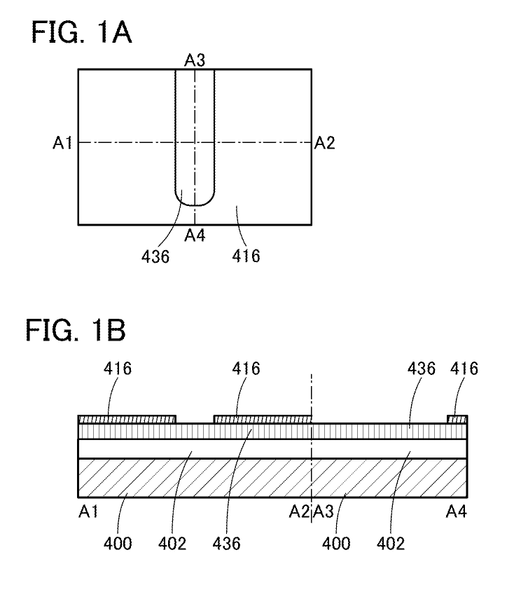

Next, a method for manufacturing a transistor of one embodiment of the present invention is described with reference to FIGS. 1A and 1B, FIGS. 2A and 2B, and FIGS. 3A and 3B.

First, a substrate 400 is prepared. Next, an insulator 402 is deposited. Next, a semiconductor 436 is deposited. Then, a conductor to be a conductor 416 is deposited. Next, a resist is formed. Then, the conductor to be the conductor 416 is etched using the resist as a mask, whereby the conductor 416 is formed. After that, the resist is removed (see FIGS. 1A and 1B). FIG. 1A is a top view illustrating the method for manufacturing the transistor and FIG. 1B is a cross-sectional view taken along dashed-dotted line A1-A2 and dashed-dotted line A3-A4 in FIG. 1A.

As illustrated in FIG. 1A, a corner portion of the conductor 416 has a round shape. That is, a portion between two side surfaces of the conductor 416 has a curved surface.

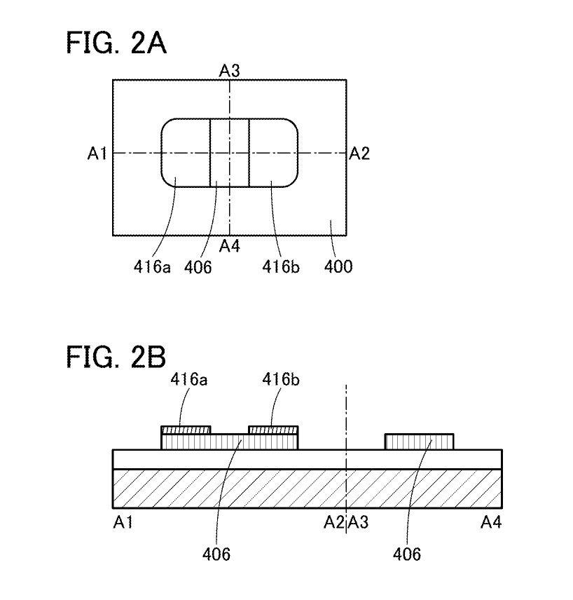

Next, a resist is formed. Then, the conductor 416 is etched using the resist as a mask, whereby a conductor 416a and a conductor 416b are formed. The semiconductor 436 is etched using the resist and/or the conductors 416a and 416b as a mask(s), whereby an island-shaped semiconductor 406 is formed. After that, the resist is removed (see FIGS. 2A and 2B). FIG. 2A is a top view illustrating the method for manufacturing the transistor and FIG. 2B is a cross-sectional view taken along dashed-dotted line A1-A2 and dashed-dotted line A3-A4 in FIG. 2A.

As illustrated in FIG. 2A, corner portions of the semiconductor 406, the conductor 416a, and the conductor 416b each have a curved surface. Here, it is to be noted that each of the conductor 416a and the conductor 416b has a square-cornered shape at the corner portion on the side where it faces the other. Specifically, each of the conductor 416a and the conductor 416b has a portion with a small radius of curvature at the corner portion on the side where it faces the other. This is because the corner portion of the conductor 416 which has a curved surface and which is illustrated in FIG. 1A is removed in FIG. 2A.

Although the conductor 416 and the semiconductor 436 are processed after formation of the conductor 416 over the semiconductor 436 here so that the semiconductor 406, the conductor 416a, and the conductor 416b are formed, a method for manufacturing a transistor of one embodiment of the present invention is not limited to the above. For example, first, a conductor is deposited over the semiconductor 436. Then, the semiconductor 436 and the conductor are processed to form the semiconductor 406 and a conductor having a top surface shape similar to that of the semiconductor 406. Next, the conductor is processed to form the conductor 416a and the conductor 416b. Through this process, the shape illustrated in FIGS. 2A and 2B can also be obtained.

Next, an insulator 412 is deposited. Next, a conductor to be a conductor 404 is deposited. Next, a resist is formed over the conductor to be the conductor 404. Then, the conductor to be the conductor 404 is etched using the resist as a mask, whereby the conductor 404 is formed. After that, the resist is removed. Then, an insulator 408 is deposited.

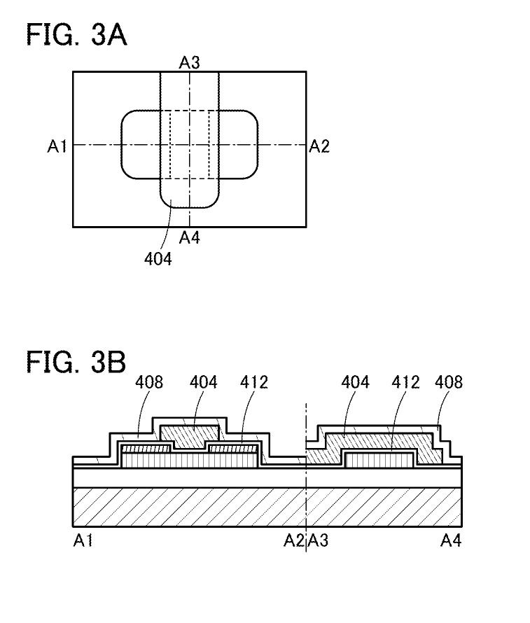

Through the above steps, the transistor can be manufactured (see FIGS. 3A and 3B). FIG. 3A is a top view illustrating the method for manufacturing the transistor and FIG. 3B is a cross-sectional view taken along dashed-dotted line A1-A2 and dashed-dotted line A3-A4 in FIG. 3A.

As illustrated in FIG. 3A, a corner portion of the conductor 404 has a round shape. That is, a portion between two side surfaces of the conductor 404 has a curved surface.

In the transistor manufactured as described above, the conductor 404 has a function of a gate electrode. The insulator 412 has a function of a gate insulator. The conductor 416a and the conductor 416b have functions of a source electrode and a drain electrode. The semiconductor 406 includes a channel formation region.

Note that the transistor does not necessarily include the substrate 400. The transistor does not necessarily include the insulator 402. The transistor does not necessarily include the insulator 408.

In the transistor illustrated in FIGS. 3A and 3B, the corner portions of the conductor 416a and the conductor 416b serving as the source electrode and the drain electrode each have a square-cornered shape. Specifically, each of the conductor 416a and the conductor 416b has a portion with a smaller radius of curvature at the corner portion on the side where it faces the other than at the corner portion on the other side where it does not face the other. Thus, a channel length of the transistor at the corner portions of the conductor 416a and the conductor 416b is hardly different from a channel length at the other portions. Accordingly, in the channel formation region, ease of current flow is not different between regions. In other words, the channel width does not become smaller than designed and thus, on-state current higher than that in the transistor illustrated in FIGS. 10A and 10B can be obtained. Moreover, the channel formation region is formed to have the same or substantially the same shape, which inhibit variation in electrical characteristics between a plurality of transistors.

### <Method 2 for Manufacturing Transistor>

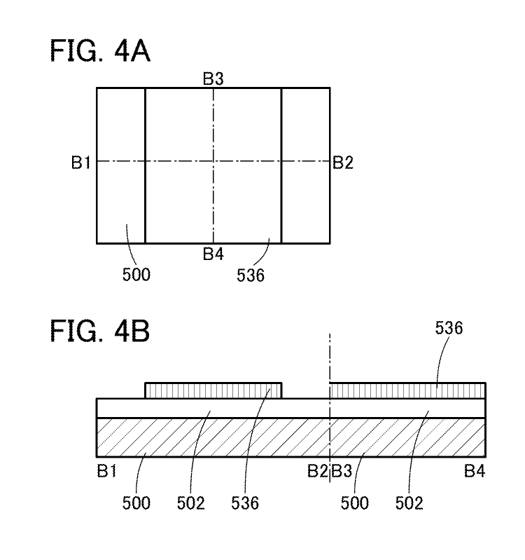

Next, a method for manufacturing a transistor of one embodiment of the present invention is described with reference to FIGS. 4A and 4B, FIGS. 5A and 5B, FIGS. 6A and 6B, and FIGS. 7A and 7B.

First, a substrate 500 is prepared. Next, an insulator 502 is deposited. Next, a semiconductor to be a semiconductor 536 is deposited. Next, a resist is formed. Then, the semiconductor to be the semiconductor 536 is etched using the resist as a mask, whereby the semiconductor 536 is formed. After that, the resist is removed (see FIGS. 4A and 4B). FIG. 4A is a top view illustrating the method for manufacturing the transistor and FIG. 4B is a cross-sectional view taken along dashed-dotted line B1-B2 and dashed-dotted line B3-B4 in FIG. 4A.

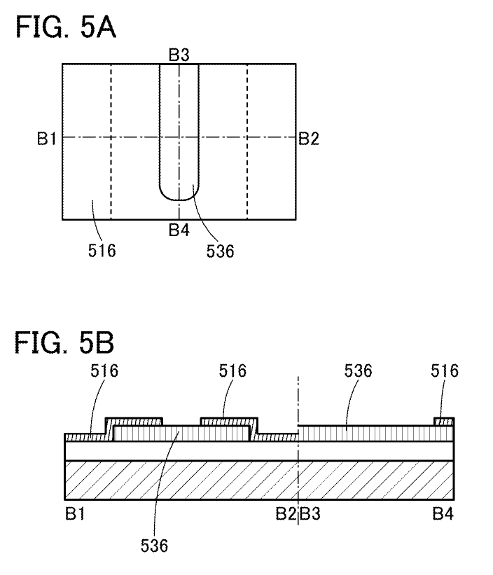

Next, a conductor to be a conductor 516 is deposited. Next, a resist is formed. Then, the conductor to be the conductor 516 is etched using the resist as a mask, whereby the conductor 516 is formed. After that, the resist is removed (see FIGS. 5A and 5B). FIG. 5A is a top view illustrating the method for manufacturing the transistor and FIG. 5B is a cross-sectional view taken along dashed-dotted line B1-B2 and dashed-dotted line B3-B4 in FIG. 5A.

As illustrated in FIG. 5A, a corner portion of the conductor 516 has a round shape. That is, a portion between two side surfaces of the conductor 516 has a curved surface.

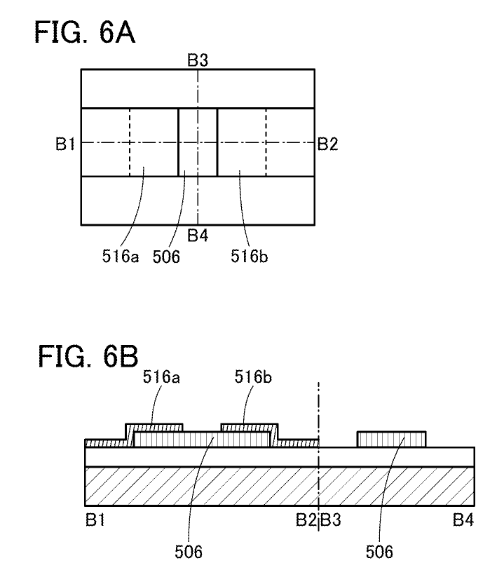

Next, a resist is formed. Then, the conductor 516 is etched using the resist as a mask, whereby a conductor 516a and a conductor 516b are formed. The semiconductor 536 is etched using the resist and/or the conductors 516a and 516b as a mask(s), whereby an island-shaped semiconductor 506 is formed. After that, the resist is removed (see FIGS. 6A and 6B). FIG. 6A is a top view illustrating the method for manufacturing the transistor and FIG. 6B is a cross-sectional view taken along dashed-dotted line B1-B2 and dashed-dotted line B3-B4 in FIG. 6A.

As illustrated in FIG. 6A, corner portions of the semiconductor 506, the conductor 516a, and the conductor 516b each have a square-cornered shape. Specifically, each of the semiconductor 506, the conductor 516a, and the conductor 516b has a portion with a small radius of curvature at the corner. This is because the corner portion of the conductor 516 which has a curved surface and which is illustrated in FIG. 5A is removed in FIG. 6A.

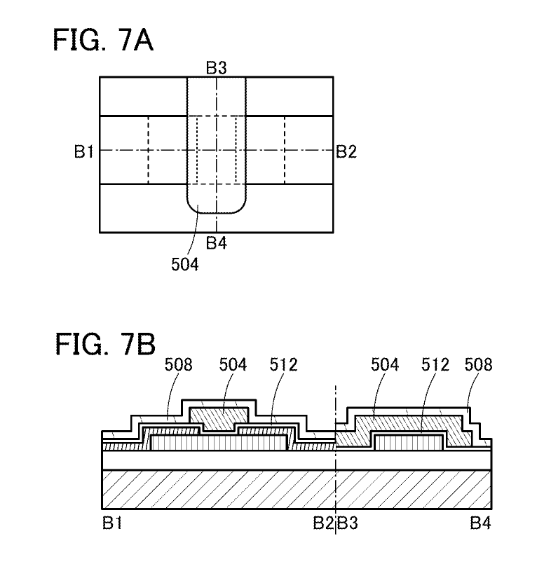

Next, an insulator 512 is deposited. Next, a conductor to be a conductor 504 is deposited. Next, a resist is formed over the conductor to be the conductor 504. Then, the conductor to be the conductor 504 is etched using the resist as a mask, whereby the conductor 504 is formed. After that, the resist is removed. Then, an insulator 508 is deposited. Through the above steps, the transistor can be manufactured (see FIGS. 7A and 7B). FIG. 7A is a top view illustrating the method for manufacturing the transistor and FIG. 7B is a cross-sectional view taken along dashed-dotted line B1-B2 and dashed-dotted line B3-B4 in FIG. 7A.

As illustrated in FIG. 7A, a corner portion of the conductor 504 has a round shape. That is, a portion between two side surfaces of the conductor 504 has a curved surface.

In the transistor manufactured as described above, the conductor 504 has a function of a gate electrode. The insulator 512 has a function of a gate insulator. The conductor 516a and the conductor 516b have functions of a source electrode and a drain electrode. The semiconductor 506 includes a channel formation region.

Note that the transistor does not necessarily include the substrate 500. The transistor does not necessarily include the insulator 502. The transistor does not necessarily include the insulator 508.

In the transistor illustrated in FIGS. 7A and 7B, the corner portions of the conductor 516a and the conductor 516b serving as the source electrode and the drain electrode each have a square-cornered shape. Specifically, each of the conductor 516a and the conductor 516b has a portion with a small radius of curvature at the corner portion, which is, for example, smaller than that of the corner portion of the conductor 504. Thus, a channel length of the transistor at the corner portions of the conductor 516a and the conductor 516b is hardly different from a channel length at the other portions. Accordingly, in the channel formation region, ease of current flow is not different between regions. In other words, the channel width does not become smaller than designed and thus, on-state current higher than that in the transistor illustrated in FIGS. 10A and 10B can be obtained. Moreover, the corner portion is formed to have the same or substantially the same shape, which inhibit variation in electrical characteristics between a plurality of transistors.

### <Modification Example of Transistor>

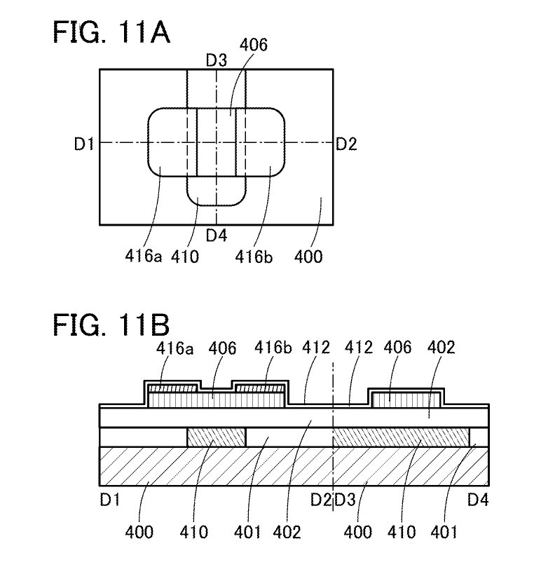

Note that although the transistors illustrated in FIGS. 3A and 3B and FIGS. 7A and 7B have a top-gate structure, a transistor of one embodiment of the present invention is not limited to this structure. For example, a transistor with a bottom-gate structure as illustrated in FIGS. 11A and 11B is also a transistor of one embodiment of the present invention.

FIG. 11A is a top view illustrating the transistor and FIG. 11B is a cross-sectional view taken along dashed-dotted line D1-D2 and dashed-dotted line D3-D4 in FIG. 11A.

The transistor illustrated in FIGS. 11A and 11B is different from that illustrated in FIGS. 3A and 3B in layout of the conductor having a function of the gate electrode. Specifically, the conductor 410 having a function of the gate electrode is provided over the substrate 400. The insulator 402 has a function of a gate insulator. Note that although the conductor 410 is embedded in the insulator 401, the present invention is not limited to this shape.

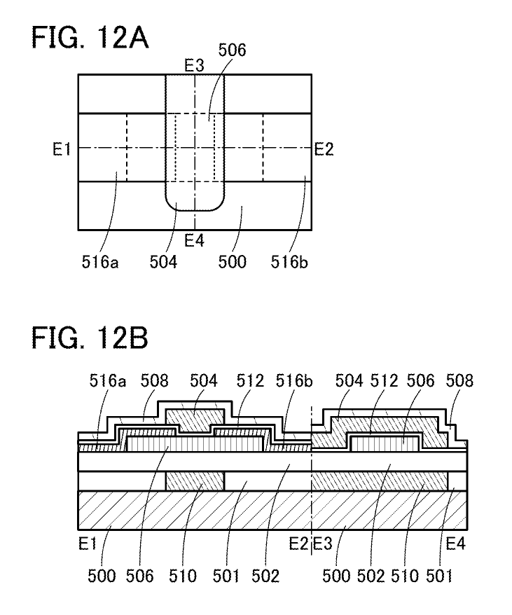

In addition, a transistor including both a top gate and a bottom gate as illustrated in FIGS. 12A and 12B is also a transistor of one embodiment of the present invention.

FIG. 12A is a top view illustrating the transistor and FIG. 12B is a cross-sectional view taken along dashed-dotted line E1-E2 and dashed-dotted line E3-E4 in FIG. 12A.

The transistor illustrated in FIGS. 12A and 12B is different from that illustrated in FIGS. 7A and 7B in layout of the conductors having functions of the gate electrodes. Specifically, a conductor 510 having a function of a gate electrode is also provided over the substrate 500.

The insulator 502 has a function of a gate insulator. Note that although the conductor 510 is embedded in the insulator 501, the present invention is not limited to this shape.

Note that FIGS. 11A and 11B and FIGS. 12A and 12B are mere examples. Therefore, besides them, the layouts of any components may be modified in any drawings referred to in this specification.

### <Components of Transistor>

Components of a transistor of one embodiment of the present invention are described below.

As the substrate 400, an insulator substrate, a semiconductor substrate, or a conductor substrate may be used, for example. As the insulator substrate, a glass substrate, a quartz substrate, a sapphire substrate, a stabilized zirconia substrate (e.g., an yttria-stabilized zirconia substrate), or a resin substrate is used, for example. As the semiconductor substrate, a single material semiconductor substrate of silicon, germanium, or the like or a compound semiconductor substrate of silicon carbide, silicon germanium, gallium arsenide, indium phosphide, zinc oxide, gallium oxide, or the like is used, for example. A semiconductor substrate in which an insulator region is provided in the above semiconductor substrate, e.g., a silicon on insulator (SOI) substrate or the like is used. As the conductor substrate, a graphite substrate, a metal substrate, an alloy substrate, a conductive resin substrate, or the like is used. A substrate including a metal nitride, a substrate including a metal oxide, or the like is used. An insulator substrate provided with a conductor or a semiconductor, a semiconductor substrate provided with a conductor or an insulator, a conductor substrate provided with a semiconductor or an insulator, or the like is used. Alternatively, any of these substrates over which an element is provided may be used. As the element provided over the substrate, a capacitor, a resistor, a switching element, a light-emitting element, a memory element, or the like is used.

Alternatively, a flexible substrate may be used as the substrate 400. As a method for providing a transistor over a flexible substrate, there is a method in which the transistor is formed over a non-flexible substrate and then the transistor is separated and transferred to the substrate 400 which is a flexible substrate. In that case, a separation layer is preferably provided between the non-flexible substrate and the transistor. As the substrate 400, a sheet, a film, or a foil containing a fiber may be used. The substrate 400 may have elasticity. The substrate 400 may have a property of returning to its original shape when bending or pulling is stopped. Alternatively, the substrate 400 may have a property of not returning to its original shape. The substrate 400 has a thickness of, for example, greater than or equal to 5 μm and less than or equal to 700 μm, preferably greater than or equal to 10 μm and less than or equal to 500 μm, more preferably greater than or equal to 15 μm and less than or equal to 300 μm. When the substrate 400 has a small thickness, the weight of the semiconductor device can be reduced. When the substrate 400 has a small thickness, even in the case of using glass or the like, the substrate 400 may have elasticity or a property of returning to its original shape when bending or pulling is stopped. Therefore, an impact applied to the semiconductor device over the substrate 400, which is caused by dropping or the like, can be reduced. That is, a durable semiconductor device can be provided.

For the substrate 400 which is a flexible substrate, metal, an alloy, resin, glass, or fiber thereof can be used, for example. The flexible substrate 400 preferably has a lower coefficient of linear expansion because deformation due to an environment is suppressed. The flexible substrate 400 is formed using, for example, a material whose coefficient of linear expansion is lower than or equal to 1×10⁻³/K, lower than or equal to 5×10⁻⁵/K, or lower than or equal to 1×10⁻⁵/K. Examples of the resin include polyester, polyolefin, polyamide (e.g., nylon or aramid), polyimide, polycarbonate, and acrylic. In particular, aramid is preferably used for the flexible substrate 400 because of its low coefficient of linear expansion.

For the substrate 500 and the substrate 600, the description of the substrate 400 is referred to.

The insulator 401 may be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 401 may be formed using, for example, aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

The insulator 401 may have a function of preventing diffusion of impurities from the substrate 400 or the like. In the case where the semiconductor 406 is an oxide semiconductor, the insulator 401 can have a function of supplying oxygen to the semiconductor 406.

For the insulator 501, the description of the insulator 401 is referred to.

The conductor 410 may be formed to have a single-layer structure or a stacked-layer structure using a conductor containing one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten, for example. An alloy or a compound containing the above element may be used, for example, and a conductor containing aluminum, a conductor containing copper and titanium, a conductor containing copper and manganese, a conductor containing indium, tin, and oxygen, a conductor containing titanium and nitrogen, or the like may be used.

For the conductor 510, the description of the conductor 410 is referred to.

The insulator 402 may be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 402 may be formed using, for example, aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

The insulator 402 may have a function of preventing diffusion of impurities from the substrate 400 or the like. In the case where the semiconductor 406 is an oxide semiconductor, the insulator 402 can have a function of supplying oxygen to the semiconductor 406.

The insulator 402 is preferably an insulator containing excess oxygen.

The insulator containing excess oxygen means an insulator from which oxygen is released by heat treatment, for example. Silicon oxide containing excess oxygen means silicon oxide which can release oxygen by heat treatment or the like, for example. Therefore, the insulator 402 is an insulator in which oxygen can be moved. In other words, the insulator 402 may be an insulator having an oxygen-transmitting property. For example, the insulator 402 may be an insulator having a higher oxygen-transmitting property than the semiconductor 406.

The insulator containing excess oxygen has a function of reducing oxygen vacancies in the semiconductor 406 in some cases. Such oxygen vacancies form DOS in the semiconductor 406 and serve as hole traps or the like. In addition, hydrogen comes into the site of such oxygen vacancies and forms electrons serving as carriers. Therefore, by reducing the oxygen vacancies in the semiconductor 406, the transistor can have stable electrical characteristics.

Here, an insulator from which oxygen is released by heat treatment may release oxygen, the amount of which is higher than or equal to 1×10¹⁸ atoms/cm³, higher than or equal to 1×10¹⁹ atoms/cm³, or higher than or equal to 1×10²⁰ atoms/cm³ (converted into the number of oxygen atoms) in TDS analysis in the range of a surface temperature of 100° C. to 700° C. or 100° C. to 500° C.

Here, the method for measuring the amount of released oxygen using TDS analysis is described below.

The total amount of released gas from a measurement sample in TDS analysis is proportional to the integral value of the ion intensity of the released gas. Then, comparison with a reference sample is made, whereby the total amount of released gas can be calculated.

For example, the number of released oxygen molecules (N_{O2}) from a measurement sample can be calculated according to the following formula using the TDS results of a silicon substrate containing hydrogen at a predetermined density, which is a reference sample, and the TDS results of the measurement sample. Here, all gases having a mass-to-charge ratio of 32 which are obtained in the TDS analysis are assumed to originate from an oxygen molecule. Note that CH₃OH, which is a gas having the mass-to-charge ratio of 32, is not taken into consideration because it is unlikely to be present. Furthermore, an oxygen molecule including an oxygen atom having a mass number of 17 or 18 which is an isotope of an oxygen atom is also not taken into consideration because the proportion of such a molecule in the natural world is minimal.

N_{O2}═N_{H2}/S_{H2}×S_{O2}×α

The value N_{H2} is obtained by conversion of the number of hydrogen molecules desorbed from the reference sample into densities. The value S_{H2} is the integral value of ion intensity in the case where the reference sample is subjected to the TDS analysis. Here, the reference value of the reference sample is set to N_{H2}/S_{H2}. The value S_{O2} is the integral value of ion intensity when the measurement sample is analyzed by TDS. The value a is a coefficient affecting the ion intensity in the TDS analysis. Refer to Japanese Published Patent Application No. H6-275697 for details of the above formula. The amount of released oxygen is measured with a thermal desorption spectroscopy apparatus produced by ESCO Ltd., EMD-WA1000S/W using a silicon substrate containing hydrogen atoms at 1×10¹⁶ atoms/cm², for example, as the reference sample.

Furthermore, in the TDS analysis, oxygen is partly detected as an oxygen atom. The ratio between oxygen molecules and oxygen atoms can be calculated from the ionization rate of the oxygen molecules. Note that since the above a includes the ionization rate of the oxygen molecules, the amount of the released oxygen atoms can also be estimated through the evaluation of the amount of the released oxygen molecules.

Note that N_{O2} is the amount of the released oxygen molecules. The amount of released oxygen in the case of being converted into oxygen atoms is twice the amount of the released oxygen molecules.

Furthermore, the insulator from which oxygen is released by heat treatment may contain a peroxide radical. Specifically, the spin density attributed to the peroxide radical is greater than or equal to 5×10¹⁷ spins/cm³. Note that the insulator containing a peroxide radical may have an asymmetric signal with a g factor of approximately 2.01 in electron spin resonance.

The insulator containing excess oxygen may be formed using oxygen-excess silicon oxide (SiO_{X} (X>2)). In the oxygen-excess silicon oxide (SiO_{X} (X>2)), the number of oxygen atoms per unit volume is more than twice the number of silicon atoms per unit volume. The number of silicon atoms and the number of oxygen atoms per unit volume are measured by Rutherford backscattering spectrometry (RBS).

For the insulator 502 and the insulator 602, the description of the insulator 402 is referred to.

Each of the conductor 416a and the conductor 416b may be formed to have, for example, a single-layer structure or a stacked-layer structure including a conductor containing one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten. An alloy or a compound containing the above element may be used, for example, and a conductor containing aluminum, a conductor containing copper and titanium, a conductor containing copper and manganese, a conductor containing indium, tin, and oxygen, a conductor containing titanium and nitrogen, or the like may be used.

For the conductor 516a, the conductor 516b, the conductor 616a, and the conductor 616b, the description of the conductor 416a and the conductor 416b is referred to.

The insulator 412 may be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 412 may be formed using, for example, aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

For the insulator 512 and the insulator 612, the description of the insulator 412 is referred to.

The conductor 404 may be formed to have, for example, a single-layer structure or a stacked-layer structure including a conductor containing one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten. An alloy or a compound containing the above element may be used, for example, and a conductor containing aluminum, a conductor containing copper and titanium, a conductor containing copper and manganese, a conductor containing indium, tin, and oxygen, a conductor containing titanium and nitrogen, or the like may be used.

For the conductor 504 and the conductor 604, the description of the conductor 404 is referred to.

The insulator 408 may be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 408 may be preferably formed to have, for example, a single-layer structure or a stacked-layer structure including an insulator containing aluminum oxide, silicon nitride oxide, silicon nitride, gallium oxide, yttrium oxide, zirconium oxide, lanthanum oxide, neodymium oxide, hafnium oxide, or tantalum oxide.

For the insulator 508 and the insulator 608, the description of the insulator 408 is referred to.

An oxide semiconductor is preferably used as the semiconductor 406. However, silicon (including strained silicon), germanium, silicon germanium, silicon carbide, gallium arsenide, aluminum gallium arsenide, indium phosphide, gallium nitride, an organic semiconductor, or the like can be used in some cases.

### <Structure of Oxide Semiconductor>

The structure of an oxide semiconductor is described below.

An oxide semiconductor is classified into a single crystal oxide semiconductor and a non-single-crystal oxide semiconductor. Examples of a non-single-crystal oxide semiconductor include a c-axis aligned crystalline oxide semiconductor (CAAC-OS), a polycrystalline oxide semiconductor, a nanocrystalline oxide semiconductor (nc-OS), an amorphous-like oxide semiconductor (a-like OS), and an amorphous oxide semiconductor.

From another perspective, an oxide semiconductor is classified into an amorphous oxide semiconductor and a crystalline oxide semiconductor. In addition, examples of a crystalline oxide semiconductor include a single crystal oxide semiconductor, a CAAC-OS, a polycrystalline oxide semiconductor, and an nc-OS.

It is known that an amorphous structure is generally defined as being metastable and unfixed, and being isotropic and having no non-uniform structure. In other words, an amorphous structure has a flexible bond angle and a short-range order but does not have a long-range order.

This means that an inherently stable oxide semiconductor cannot be regarded as a completely amorphous oxide semiconductor. Moreover, an oxide semiconductor that is not isotropic (e.g., an oxide semiconductor that has a periodic structure in a microscopic region) cannot be regarded as a completely amorphous oxide semiconductor. Note that an a-like OS has a periodic structure in a microscopic region, but at the same time has a void and has an unstable structure. For this reason, an a-like OS has physical properties similar to those of an amorphous oxide semiconductor.

### <CAAC-OS>

First, a CAAC-OS is described.

A CAAC-OS is one of oxide semiconductors having a plurality of c-axis aligned crystal parts (also referred to as pellets).

In a combined analysis image (also referred to as a high-resolution TEM image) of a bright-field image and a diffraction pattern of a CAAC-OS, which is obtained using a transmission electron microscope (TEM), a plurality of pellets can be observed. However, in the high-resolution TEM image, a boundary between pellets, that is, a grain boundary is not clearly observed. Thus, in the CAAC-OS, a reduction in electron mobility due to the grain boundary is less likely to occur.

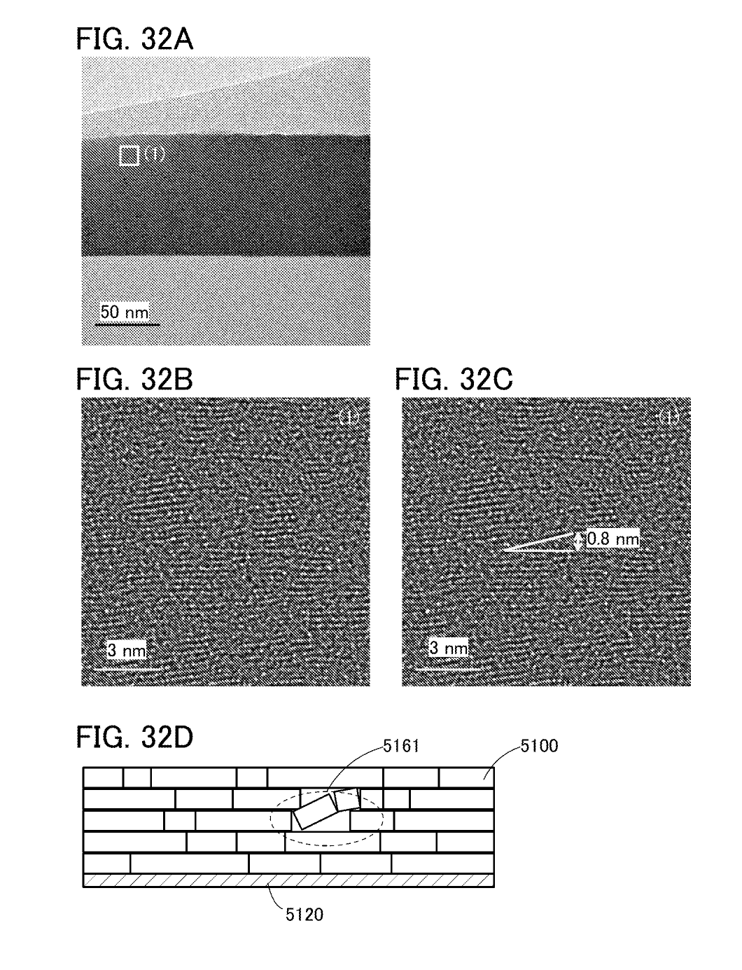

The CAAC-OS observed with a TEM is described below. FIG. 32A shows a high-resolution TEM image of a cross section of the CAAC-OS which is observed from a direction substantially parallel to the sample surface. The high-resolution TEM image is obtained with a spherical aberration corrector function. The high-resolution TEM image obtained with a spherical aberration corrector function is particularly referred to as a Cs-corrected high-resolution TEM image. The Cs-corrected high-resolution TEM image can be obtained with, for example, an atomic resolution analytical electron microscope JEM-ARM200F manufactured by JEOL Ltd.

FIG. 32B is an enlarged Cs-corrected high-resolution TEM image of a region (1) in FIG. 32A. FIG. 32B shows that metal atoms are arranged in a layered manner in a pellet. Each metal atom layer has a configuration reflecting unevenness of a surface over which a CAAC-OS film is formed (hereinafter, the surface is referred to as a formation surface) or a top surface of the CAAC-OS, and is arranged parallel to the formation surface or the top surface of the CAAC-OS.

As shown in FIG. 32B, the CAAC-OS has a characteristic atomic arrangement. The characteristic atomic arrangement is denoted by an auxiliary line in FIG. 32C. FIGS. 32B and 32C prove that the size of a pellet is greater than or equal to 1 nm, or greater than or equal to 3 nm, and the size of a space caused by tilt of the pellets is approximately 0.8 nm. Therefore, the pellet can also be referred to as a nanocrystal (nc). Furthermore, a CAAC-OS can be referred to as an oxide semiconductor including c-axis aligned nanocrystals (CANC).

Here, according to the Cs-corrected high-resolution TEM images, the schematic arrangement of pellets 5100 of a CAAC-OS over a substrate 5120 is illustrated by such a structure in which bricks or blocks are stacked (see FIG. 32D). The part in which the pellets are tilted as observed in FIG. 32C corresponds to a region 5161 shown in FIG. 32D.

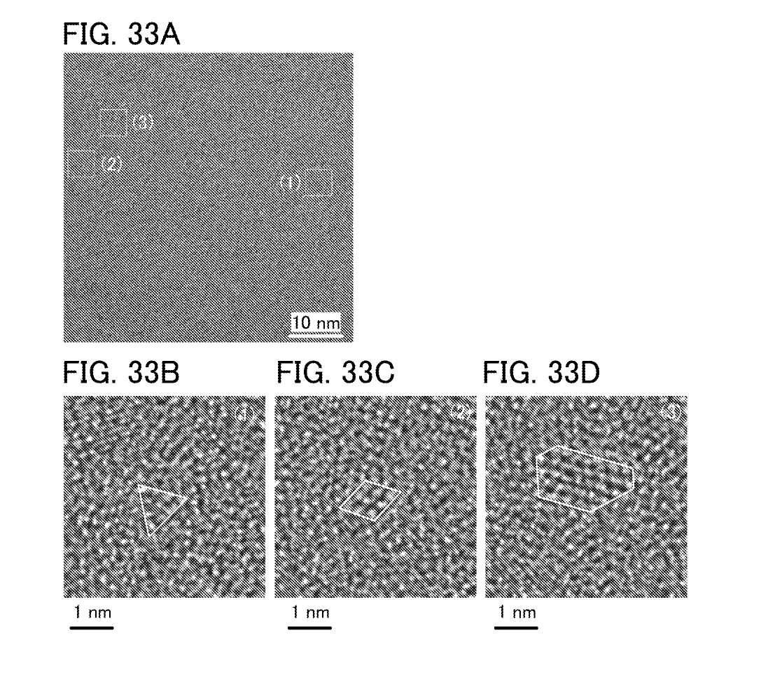

FIG. 33A shows a Cs-corrected high-resolution TEM image of a plane of the CAAC-OS observed from a direction substantially perpendicular to the sample surface. FIGS. 33B, 33C, and 33D are enlarged Cs-corrected high-resolution TEM images of regions (1), (2), and (3) in FIG. 33A, respectively. FIGS. 33B, 33C, and 33D indicate that metal atoms are arranged in a triangular, quadrangular, or hexagonal configuration in a pellet. However, there is no regularity of arrangement of metal atoms between different pellets.

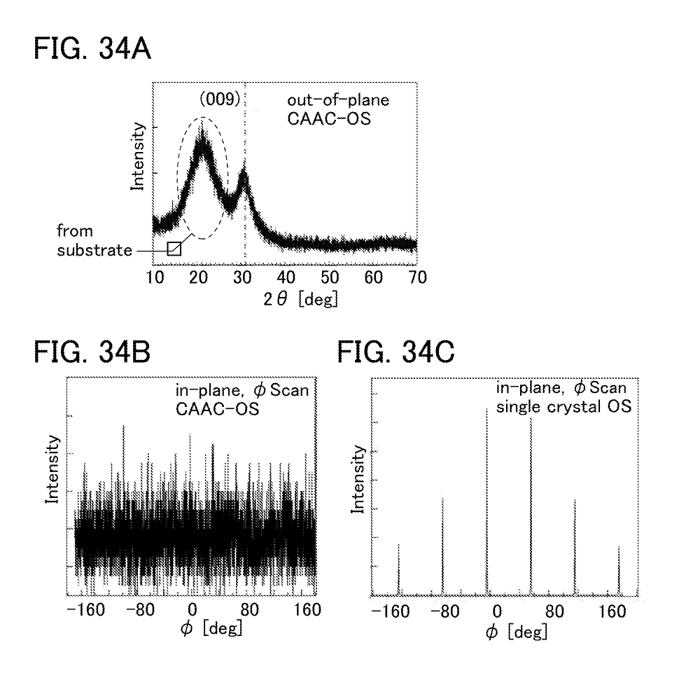

Next, a CAAC-OS analyzed by X-ray diffraction (XRD) is described. For example, when the structure of a CAAC-OS including an InGaZnO₄ crystal is analyzed by an out-of-plane method, a peak appears at a diffraction angle (2θ) of around 31° as shown in FIG. 34A. This peak is derived from the (009) plane of the InGaZnO₄ crystal, which indicates that crystals in the CAAC-OS have c-axis alignment, and that the c-axes are aligned in a direction substantially perpendicular to the formation surface or the top surface of the CAAC-OS.

Note that in structural analysis of the CAAC-OS by an out-of-plane method, another peak may appear when 2θ is around 36°, in addition to the peak at 2θ of around 31°. The peak of 2θ at around 36° indicates that a crystal having no c-axis alignment is included in part of the CAAC-OS. It is preferable that in the CAAC-OS analyzed by an out-of-plane method, a peak appear when 2θ is around 31° and that a peak not appear when 2θ is around 36°.

On the other hand, in structural analysis of the CAAC-OS by an in-plane method in which an X-ray is incident on a sample in a direction substantially perpendicular to the c-axis, a peak appears when 2θ is around 56°. This peak is derived from the (110) plane of the InGaZnO₄ crystal. In the case of the CAAC-OS, when analysis (φ scan) is performed with 2θ fixed at around 56° and with the sample rotated using a normal vector of the sample surface as an axis (φ axis), as shown in FIG. 34B, a peak is not clearly observed. In contrast, in the case of a single crystal oxide semiconductor of InGaZnO₄, when φ scan is performed with 2 θ fixed at around 56°, as shown in FIG. 34C, six peaks which are derived from crystal planes equivalent to the (110) plane are observed. Accordingly, the structural analysis using XRD shows that the directions of a-axes and b-axes are irregularly oriented in the CAAC-OS.

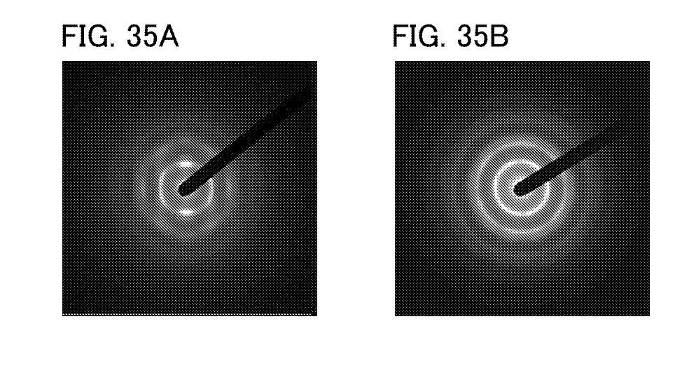

Next, a CAAC-OS analyzed by electron diffraction is described. For example, when an electron beam with a probe diameter of 300 nm is incident on a CAAC-OS including an InGaZnO₄ crystal in a direction parallel to the sample surface, a diffraction pattern (also referred to as a selected-area transmission electron diffraction pattern) shown in FIG. 35A can be obtained. In this diffraction pattern, spots derived from the (009) plane of an InGaZnO₄ crystal are included. Thus, the electron diffraction also indicates that pellets included in the CAAC-OS have c-axis alignment and that the c-axes are aligned in a direction substantially perpendicular to the formation surface or the top surface of the CAAC-OS. Meanwhile, FIG. 35B shows a diffraction pattern obtained in such a manner that an electron beam with a probe diameter of 300 nm is incident on the same sample in a direction perpendicular to the sample surface. As shown in FIG. 35B, a ring-like diffraction pattern is observed. Thus, the electron diffraction also indicates that the a-axes and b-axes of the pellets included in the CAAC-OS do not have regular alignment. The first ring in FIG. 35B is considered to be derived from the (010) plane, the (100) plane, and the like of the InGaZnO₄ crystal. Furthermore, it is supposed that the second ring in FIG. 35B is derived from the (110) plane and the like.

As described above, the CAAC-OS is an oxide semiconductor with high crystallinity. Entry of impurities, formation of defects, or the like might decrease the crystallinity of an oxide semiconductor. This means that the CAAC-OS has small amounts of impurities and defects (e.g., oxygen vacancy).

Note that the impurity means an element other than the main components of the oxide semiconductor, such as hydrogen, carbon, silicon, or a transition metal element. For example, an element (specifically, silicon or the like) having higher strength of bonding to oxygen than a metal element included in an oxide semiconductor extracts oxygen from the oxide semiconductor, which results in disorder of the atomic arrangement and reduced crystallinity of the oxide semiconductor. A heavy metal such as iron or nickel, argon, carbon dioxide, or the like has a large atomic radius (or molecular radius), and thus disturbs the atomic arrangement of the oxide semiconductor and decreases crystallinity.

The characteristics of an oxide semiconductor having impurities or defects might be changed by light, heat, or the like. Impurities included in the oxide semiconductor might serve as carrier traps or carrier generation sources, for example. Furthermore, oxygen vacancy in the oxide semiconductor serves as a carrier trap or serves as a carrier generation source when hydrogen is captured therein.

The CAAC-OS having small amounts of impurities and oxygen vacancy is an oxide semiconductor with low carrier density (specifically, lower than 8×10¹¹/cm³, preferably lower than 1×10¹¹/cm³, further preferably lower than 1×10¹⁰/cm³, and is higher than or equal to 1×10⁻⁹/cm³). Such an oxide semiconductor is referred to as a highly purified intrinsic or substantially highly purified intrinsic oxide semiconductor. A CAAC-OS has a low impurity concentration and a low density of defect states. Thus, the CAAC-OS can be referred to as an oxide semiconductor having stable characteristics.

<nc-OS>

Next, an nc-OS is described.

An nc-OS has a region in which a crystal part is observed and a region in which a crystal part is not clearly observed in a high-resolution TEM image. In most cases, the size of a crystal part included in the nc-OS is greater than or equal to 1 nm and less than or equal to 10 nm, or greater than or equal to 1 nm and less than or equal to 3 nm. Note that an oxide semiconductor including a crystal part whose size is greater than 10 nm and less than or equal to 100 nm is sometimes referred to as a microcrystalline oxide semiconductor. In a high-resolution TEM image of the nc-OS, for example, a grain boundary is not clearly observed in some cases. Note that there is a possibility that the origin of the nanocrystal is the same as that of a pellet in a CAAC-OS. Therefore, a crystal part of the nc-OS may be referred to as a pellet in the following description.

In the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. There is no regularity of crystal orientation between different pellets in the nc-OS. Thus, the orientation of the whole film is not observed. Accordingly, the nc-OS cannot be distinguished from an a-like OS and an amorphous oxide semiconductor, depending on an analysis method. For example, when the nc-OS is analyzed by an out-of-plane method using an X-ray beam having a diameter larger than the size of a pellet, a peak which shows a crystal plane does not appear. Furthermore, a diffraction pattern like a halo pattern is observed when the nc-OS is subjected to electron diffraction using an electron beam with a probe diameter (e.g., 50 nm or larger) that is larger than the size of a pellet. Meanwhile, spots appear in a nanobeam electron diffraction pattern of the nc-OS when an electron beam having a probe diameter close to or smaller than the size of a pellet is applied. Moreover, in a nanobeam electron diffraction pattern of the nc-OS, regions with high luminance in a circular (ring) pattern are shown in some cases. Also in a nanobeam electron diffraction pattern of the nc-OS, a plurality of spots are shown in a ring-like region in some cases.

Since there is no regularity of crystal orientation between the pellets (nanocrystals) as mentioned above, the nc-OS can also be referred to as an oxide semiconductor including random aligned nanocrystals (RANC) or an oxide semiconductor including non-aligned nanocrystals (NANC).

The nc-OS is an oxide semiconductor that has high regularity as compared to an amorphous oxide semiconductor. Therefore, the nc-OS is likely to have a lower density of defect states than an a-like OS and an amorphous oxide semiconductor. Note that there is no regularity of crystal orientation between different pellets in the nc-OS. Therefore, the nc-OS has a higher density of defect states than the CAAC-OS.

<a-like OS>

An a-like OS has a structure between those of the nc-OS and the amorphous oxide semiconductor.

In a high-resolution TEM image of the a-like OS, a void may be observed.

Furthermore, in the high-resolution TEM image, there are a region where a crystal part is clearly observed and a region where a crystal part is not observed.

The a-like OS has an unstable structure because it contains a void. To verify that an a-like OS has an unstable structure as compared with a CAAC-OS and an nc-OS, a change in structure caused by electron irradiation is described below.

An a-like OS (sample A), an nc-OS (sample B), and a CAAC-OS (sample C) are prepared as samples subjected to electron irradiation. Each of the samples is an In—Ga—Zn oxide.

First, a high-resolution cross-sectional TEM image of each sample is obtained. The high-resolution cross-sectional TEM images show that all the samples have crystal parts.

Note that which part is regarded as a crystal part is determined as follows. It is known that a unit cell of the InGaZnO₄ crystal has a structure in which nine layers including three In—O layers and six Ga—Zn—O layers are stacked in the c-axis direction. The distance between the adjacent layers is equivalent to the lattice spacing on the (009) plane (also referred to as d value). The value is calculated to be 0.29 nm from crystal structural analysis. Accordingly, a portion where the lattice spacing between lattice fringes is greater than or equal to 0.28 nm and less than or equal to 0.30 nm is regarded as a crystal part of InGaZnO₄. Each of lattice fringes corresponds to the a-b plane of the InGaZnO₄ crystal.

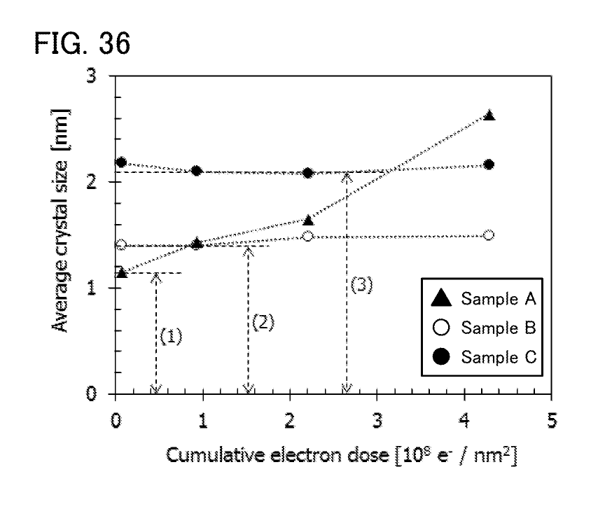

FIG. 36 shows change in the average size of crystal parts (at 22 points to 45 points) in each sample. Note that the crystal part size corresponds to the length of a lattice fringe. FIG. 36 indicates that the crystal part size in the a-like OS increases with an increase in the cumulative electron dose. Specifically, as shown by (1) in FIG. 36, a crystal part of approximately 1.2 nm at the start of TEM observation (the crystal part is also referred to as an initial nucleus) grows to a size of approximately 2.6 nm at a cumulative electron dose of 4.2×10⁸ e⁻/nm². In contrast, the crystal part size in the nc-OS and the CAAC-OS shows little change from the start of electron irradiation to a cumulative electron dose of 4.2×10⁸ e⁻/nm². Specifically, as shown by (2) and (3) in FIG. 36, the average crystal sizes in an nc-OS and a CAAC-OS are approximately 1.4 nm and approximately 2.1 nm, respectively, regardless of the cumulative electron dose.

In this manner, growth of the crystal part in the a-like OS is induced by electron irradiation. In contrast, in the nc-OS and the CAAC-OS, growth of the crystal part is hardly induced by electron irradiation. Therefore, the a-like OS has an unstable structure as compared with the nc-OS and the CAAC-OS.

The a-like OS has a lower density than the nc-OS and the CAAC-OS because it contains a void. Specifically, the density of the a-like OS is higher than or equal to 78.6% and lower than 92.3% of the density of the single crystal oxide semiconductor having the same composition. The density of each of the nc-OS and the CAAC-OS is higher than or equal to 92.3% and lower than 100% of the density of the single crystal oxide semiconductor having the same composition. Note that, as for an oxide semiconductor having a density of lower than 78% of the density of the single crystal oxide semiconductor, the deposition itself is difficult.

For example, in the case of an oxide semiconductor having an atomic ratio of In:Ga:Zn=1:1:1, the density of single crystal InGaZnO₄ with a rhombohedral crystal structure is 6.357 g/cm³. Accordingly, in the case of the oxide semiconductor having an atomic ratio of In:Ga:Zn=1:1:1, the density of the a-like OS is higher than or equal to 5.0 g/cm³ and lower than 5.9 g/cm³. For example, in the case of the oxide semiconductor having an atomic ratio of In:Ga:Zn=1:1:1, the density of each of the nc-OS and the CAAC-OS is higher than or equal to 5.9 g/cm³ and lower than 6.3 g/cm³.

Note that there is a possibility that an oxide semiconductor having a certain composition cannot exist in a single crystal structure. In that case, single crystal oxide semiconductors with different compositions are combined at an adequate ratio, which makes it possible to calculate density equivalent to that of a single crystal oxide semiconductor with the desired composition. The density of a single crystal oxide semiconductor having the desired composition can be calculated using a weighted average according to the combination ratio of the single crystal oxide semiconductors with different compositions. Note that it is preferable to use as few kinds of single crystal oxide semiconductors as possible to calculate the density.

As described above, oxide semiconductors have various structures and various properties. Note that an oxide semiconductor may be a stacked layer including two or more of an amorphous oxide semiconductor, an a-like OS, an nc-OS, and a CAAC-OS, for example.

### <Composition of Oxide Semiconductor>

Composition of an oxide semiconductor is described below. For explanation of the composition, the case of an In—M—Zn oxide is described as an example. The element M is aluminum, gallium, yttrium, tin, or the like. Other elements which can be used as the element M are boron, silicon, titanium, iron, nickel, germanium, yttrium, zirconium, molybdenum, lanthanum, cerium, neodymium, hafnium, tantalum, tungsten, and the like. Note that [In] means the atomic concentration of In, [M] means the atomic concentration of the element M, and [Zn] means the atomic concentration of Zn.

A crystal of an In—M—Zn oxide is known to have a homologous structure and is represented by InMO₃(ZnO)ₘ (m is a natural number). Since In and M can be interchanged, the crystal can also be represented by In_{1+α}M_{1-α}O₃(ZnO)ₘ. This composition is represented by any of the following: [In]:[M]:[Zn]=1+α:1−α:1, [In]:[M]:[Zn]=1+α:1−α:2, [In]:[M]:[Zn]=1+α:1−α:3, [In]:[M]:[Zn]=1+α:1−α:4, and [In]:[M]:[Zn]=1+α:1−α:5. Note that the values represent, for example, a composition that allows an oxide as a raw material mixed and subjected to baking at 1350° C. to be a solid solution.

Therefore, when an oxide has a composition close to the above composition that allows the oxide to be a solid solution, a CAAC-OS having high crystallinity can be obtained.

When a CAAC-OS is deposited, because of heating of a substrate surface (the surface on which the CAAC-OS is deposited), space heating, or the like, the composition of the film is sometimes different from that of a target as a source or the like. For example, since zinc oxide sublimates more easily than indium oxide, gallium oxide, or the like, the source and the film are likely to have different compositions. Thus, a source is preferably selected taking into account the change in composition. Note that a difference between the compositions of the source and the film is also affected by a pressure or a gas used for the deposition as well as a temperature.

Compositions of typical oxide targets and compositions of oxides deposited by sputtering using the oxide targets are described below. For example, a composition of an In—Ga—Zn oxide deposited using an oxide target having an atomic ratio of In:Ga:Zn=1:1:1 is In:Ga:Zn=1:(0.8 to 1.1):(0.5 to 0.9). A composition of an In—Ga—Zn oxide deposited using an oxide target having an atomic ratio of In:Ga:Zn=3:1:2 is In:Ga:Zn=3:(0.8 to 1.1):(1.0 to 1.8). A composition of an In—Ga—Zn oxide deposited using an oxide target having an atomic ratio of In:Ga:Zn=4:2:4.1 is In:Ga:Zn=4:(2.6 to 3.2):(2.2 to 3.4).

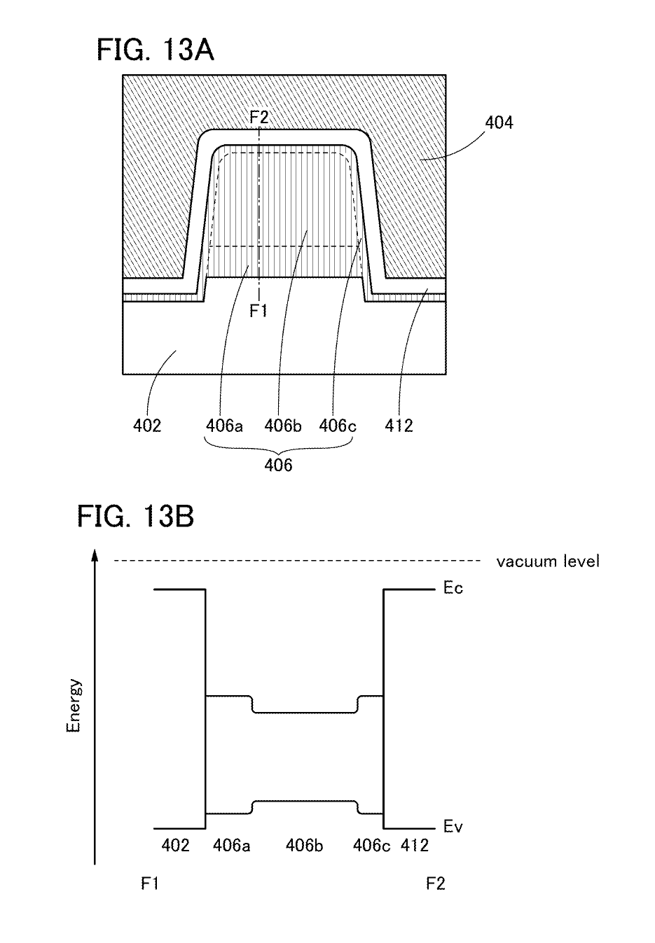

The semiconductor 406 may have a stacked-layer structure. For example, as illustrated in FIG. 13A, the semiconductor 406 may include a semiconductor 406a, a semiconductor 406b, and a semiconductor 406c. The semiconductor 406c may be part of the insulator 412. Note that FIG. 13A is part of a cross-sectional view taken along dashed-dotted line A3-A4 in FIG. 3A.

FIG. 13A illustrates an example in which part of the insulator 402 is thinned by etching.

As illustrated in FIG. 13A, in the transistor, the semiconductor 406b is electrically surrounded by an electric field of the conductor 404. A transistor structure in which a semiconductor is electrically surrounded by an electric field of a conductor is referred to as a surrounded channel (s-channel) structure. Therefore, a channel is formed in the entire semiconductor 406b (bulk) in some cases. In the s-channel structure, a large amount of current can flow between the source and the drain of the transistor, so that a high current in a conductive state (on-state current) can be obtained. Furthermore, a punch-through phenomenon can be suppressed in the s-channel structure; thus, the electrical characteristics of the transistor in a saturation region can be stable.

The s-channel structure is suitable for a miniaturized transistor because a high on-state current can be obtained. A semiconductor device including the miniaturized transistor can have a high integration degree and high density. For example, the channel length of the transistor is preferably less than or equal to 40 nm, more preferably less than or equal to 30 nm, still more preferably less than or equal to 20 nm in a region and the channel width of the transistor is preferably less than or equal to 40 nm, more preferably less than or equal to 30 nm, still more preferably less than or equal to 20 nm in a region.

An oxide semiconductor which can be used as the semiconductor 406a, the semiconductor 406b, the semiconductor 406c, or the like is described below.

The semiconductor 406b is an oxide semiconductor containing indium, for example. The oxide semiconductor 406b can have high carrier mobility (electron mobility) by containing indium, for example. The semiconductor 406b preferably contains an element M. The element M is preferably aluminum, gallium, yttrium, tin, or the like. Other elements which can be used as the element M are boron, silicon, titanium, iron, nickel, germanium, yttrium, zirconium, molybdenum, lanthanum, cerium, neodymium, hafnium, tantalum, tungsten, and the like. Note that two or more of the above elements may be used in combination as the element M. The element M is an element having high bonding energy with oxygen, for example. The element M is an element whose bonding energy with oxygen is higher than that of indium. The element M is an element that can increase the energy gap of the oxide semiconductor, for example. Furthermore, the semiconductor 406b preferably contains zinc. When the oxide semiconductor contains zinc, the oxide semiconductor is easily crystallized in some cases.

Note that the semiconductor 406b is not limited to the oxide semiconductor containing indium. The semiconductor 406b may be, for example, an oxide semiconductor which does not contain indium and contains zinc, an oxide semiconductor which does not contain indium and contains gallium, or an oxide semiconductor which does not contain indium and contains tin, e.g., a zinc tin oxide or a gallium tin oxide.

For the semiconductor 406b, an oxide with a wide energy gap may be used. For example, the energy gap of the semiconductor 406b is greater than or equal to 2.5 eV and less than or equal to 4.2 eV, preferably greater than or equal to 2.8 eV and less than or equal to 3.8 eV, more preferably greater than or equal to 3 eV and less than or equal to 3.5 eV.

For example, the semiconductor 406a and the semiconductor 406c are oxide semiconductors including one or more elements other than oxygen included in the semiconductor 406b. Since the semiconductor 406a and the semiconductor 406c each include one or more elements other than oxygen included in the semiconductor 406b, an interface state is less likely to be formed at the interface between the semiconductor 406a and the semiconductor 406b and the interface between the semiconductor 406b and the semiconductor 406c.

The semiconductor 406a, the semiconductor 406b, and the semiconductor 406c preferably include at least indium. In the case of using an In—M—Zn oxide as the semiconductor 406a, when a summation of In and M is assumed to be 100 atomic %, the proportions of In and M are preferably set to be less than 50 atomic % and greater than 50 atomic %, respectively, more preferably less than 25 atomic % and greater than 75 atomic %, respectively. In the case of using an In—M—Zn oxide as the semiconductor 406b, when a summation of In and M is assumed to be 100 atomic %, the proportions of In and M are preferably set to be greater than 25 atomic % and less than 75 atomic %, respectively, more preferably greater than 34 atomic % and less than 66 atomic %, respectively. In the case of using an In—M—Zn oxide as the semiconductor 406c, when a summation of In and M is assumed to be 100 atomic %, the proportions of In and M are preferably set to be less than 50 atomic % and greater than 50 atomic %, respectively, more preferably less than 25 atomic % and greater than 75 atomic %, respectively. Note that the semiconductor 406c may be an oxide that is a type the same as that of the semiconductor 406a. Note that the semiconductor 406a and/or the semiconductor 406c do/does not necessarily contain indium in some cases. For example, the semiconductor 406a and/or the semiconductor 406c may be gallium oxide.

As the semiconductor 406b, an oxide having an electron affinity higher than those of the semiconductors 406a and 406c is used. For example, as the semiconductor 406b, an oxide having an electron affinity higher than those of the semiconductors 406a and 406c by 0.07 eV or higher and 1.3 eV or lower, preferably 0.1 eV or higher and 0.7 eV or lower, more preferably 0.15 eV or higher and 0.4 eV or lower is used. Note that the electron affinity refers to an energy difference between the vacuum level and the bottom of the conduction band.

An indium gallium oxide has low electron affinity and a high oxygen-blocking property. Therefore, the semiconductor 406c preferably includes an indium gallium oxide. The gallium atomic ratio [Ga/(In+Ga)] is, for example, higher than or equal to 70%, preferably higher than or equal to 80%, more preferably higher than or equal to 90%.

At this time, when a gate voltage is applied, a channel is formed in the semiconductor 406b having the highest electron affinity in the semiconductor 406a, the semiconductor 406b, and the semiconductor 406c.

FIG. 13B is a band diagram taken along dashed-dotted line F1-F2 in FIG. 13A. FIG. 13B shows a vacuum level (denoted by vacuum level), and an energy of the bottom of the conduction band (denoted by Ec) and an energy of the top of the valence band (denoted by Ev) of each of the layers.

Here, in some cases, there is a mixed region of the semiconductor 406a and the semiconductor 406b between the semiconductor 406a and the semiconductor 406b. Furthermore, in some cases, there is a mixed region of the semiconductor 406b and the semiconductor 406c between the semiconductor 406b and the semiconductor 406c. The mixed region has a low interface state density. For that reason, the stack including the semiconductor 406a, the semiconductor 406b, and the semiconductor 406c has a band structure where energy at each interface and in the vicinity of the interface is changed continuously (continuous junction).

At this time, electrons move mainly in the semiconductor 406b, not in the semiconductor 406a and the semiconductor 406c. As described above, when the interface state density at the interface between the semiconductor 406a and the semiconductor 406b and the interface state density at the interface between the semiconductor 406b and the semiconductor 406c are decreased, electron movement in the semiconductor 406b is less likely to be inhibited and the on-sate current of the transistor can be increased.

As factors in inhibiting electron movement are decreased, the on-state current of the transistor can be increased. For example, electrons are assumed to be efficiently moved in the case where there is no factor in inhibiting electron movement. Electron movement is inhibited, for example, in the case where physical unevenness in the channel formation region is large.

To increase the on-state current of the transistor, for example, root mean square (RMS) roughness with a measurement area of 1 μm×1 μm of a top surface or a bottom surface of the semiconductor 406b (a formation surface; here, the semiconductor 406a) is less than 1 nm, preferably less than 0.6 nm, more preferably less than 0.5 nm, still more preferably less than 0.4 nm. The average surface roughness (also referred to as Ra) with the measurement area of 1 μm×1 μm is less than 1 nm, preferably less than 0.6 nm, more preferably less than 0.5 nm, still more preferably less than 0.4 nm. The maximum difference (P−V) with the measurement area of 1 μm×1 μm is less than 10 nm, preferably less than 9 nm, more preferably less than 8 nm, still more preferably less than 7 nm. RMS roughness, Ra, and P−V can be measured using a scanning probe microscope SPA-500 manufactured by SII Nano Technology Inc.

The electron movement is also inhibited, for example, in the case where the density of defect states is high in a region where a channel is formed.

For example, in the case where the semiconductor 406b contains oxygen vacancies (also denoted by V_{O}), donor levels are formed by entry of hydrogen into sites of oxygen vacancies in some cases. A state in which hydrogen enters sites of oxygen vacancies are denoted by V_{O}H in the following description in some cases. V_{O}H is a factor in decreasing the on-state current of the transistor because V_{O}H scatters electrons. Note that sites of oxygen vacancies become more stable by entry of oxygen than by entry of hydrogen. Thus, by decreasing oxygen vacancies in the semiconductor 406b, the on-state current of the transistor can be increased in some cases.

To decrease oxygen vacancies in the semiconductor 406b, for example, there is a method in which excess oxygen in the insulator 402 is moved to the semiconductor 406b through the semiconductor 406a. In this case, the semiconductor 406a is preferably a layer having an oxygen-transmitting property (a layer through which oxygen passes or is transmitted).

In the case where the transistor has an s-channel structure, a channel is formed in the whole of the semiconductor 406b. Therefore, as the semiconductor 406b has a larger thickness, a channel region becomes larger. In other words, the thicker the semiconductor 406b is, the larger the on-state current of the transistor is. For example, the semiconductor 406b has a region with a thickness of greater than or equal to 20 nm, preferably greater than or equal to 40 nm, more preferably greater than or equal to 60 nm, still more preferably greater than or equal to 100 nm. Note that the semiconductor 406b has a region with a thickness of, for example, less than or equal to 300 nm, preferably less than or equal to 200 nm, more preferably less than or equal to 150 nm because the productivity of the semiconductor device might be decreased.

Moreover, the thickness of the semiconductor 406c is preferably as small as possible to increase the on-state current of the transistor. The semiconductor 406c has a region with a thickness of less than 10 nm, preferably less than or equal to 5 nm, more preferably less than or equal to 3 nm, for example. Meanwhile, the semiconductor 406c has a function of blocking entry of elements other than oxygen (such as hydrogen and silicon) included in the adjacent insulator into the semiconductor 406b where a channel is formed. For this reason, it is preferable that the semiconductor 406c have a certain thickness. The semiconductor 406c has a region with a thickness of greater than or equal to 0.3 nm, preferably greater than or equal to 1 nm, more preferably greater than or equal to 2 nm, for example. The semiconductor 406c preferably has an oxygen blocking property to suppress outward diffusion of oxygen released from the insulator 402 and the like.

To improve reliability, preferably, the thickness of the semiconductor 406a is large and the thickness of the semiconductor 406c is small. For example, the semiconductor 406a has a region with a thickness of, for example, greater than or equal to 10 nm, preferably greater than or equal to 20 nm, more preferably greater than or equal to 40 nm, still more preferably greater than or equal to 60 nm. When the thickness of the semiconductor 406a is made large, a distance from an interface between the adjacent insulator and the semiconductor 406a to the semiconductor 406b in which a channel is formed can be large. Since the productivity of the semiconductor device might be decreased, the semiconductor 406a has a region with a thickness of, for example, less than or equal to 200 nm, preferably less than or equal to 120 nm, more preferably less than or equal to 80 nm.

For example, a region with a silicon concentration of lower than 1×10¹⁹ atoms/cm³, preferably lower than 5×10¹⁸ atoms/cm³, more preferably lower than 2×10¹⁸ atoms/cm³ which is measured by secondary ion mass spectrometry (SIMS) is provided between the semiconductor 406b and the semiconductor 406a. A region with a silicon concentration of lower than 1×10¹⁹ atoms/cm³, preferably lower than 5×10¹⁸ atoms/cm³, more preferably lower than 2×10¹⁸ atoms/cm³ which is measured by SIMS is provided between the semiconductor 406b and the semiconductor 406c.

The semiconductor 406b has a region in which the concentration of hydrogen measured by SIMS is lower than or equal to 2×10²⁰ atoms/cm³, preferably lower than or equal to 5×10¹⁹ atoms/cm³, more preferably lower than or equal to 1×10¹⁹ atoms/cm³, still more preferably lower than or equal to 5×10¹⁸ atoms/cm³. It is preferable to reduce the concentration of hydrogen in the semiconductor 406a and the semiconductor 406c in order to reduce the concentration of hydrogen in the semiconductor 406b. The semiconductor 406a and the semiconductor 406c each have a region in which the concentration of hydrogen measured by SIMS is lower than or equal to 2×10²⁰ atoms/cm³, preferably lower than or equal to 5×10¹⁹ atoms/cm³, more preferably lower than or equal to 1×10¹⁹ atoms/cm³, still more preferably lower than or equal to 5×10¹⁸ atoms/cm³. The semiconductor 406b has a region in which the concentration of nitrogen measured by SIMS is lower than 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³. It is preferable to reduce the concentration of nitrogen in the semiconductor 406a and the semiconductor 406c in order to reduce the concentration of nitrogen in the semiconductor 406b. The semiconductor 406a and the semiconductor 406c each have a region in which the concentration of nitrogen measured by SIMS is lower than 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³.

The above three-layer structure is an example. For example, a two-layer structure without the semiconductor 406a or the semiconductor 406c may be employed. A four-layer structure in which any one of the semiconductors described as examples of the semiconductor 406a, the semiconductor 406b, and the semiconductor 406c is provided under or over the semiconductor 406a or under or over the semiconductor 406c may be employed. An n-layer structure (n is an integer of 5 or more) in which any one of the semiconductors described as examples of the semiconductor 406a, the semiconductor 406b, and the semiconductor 406c is provided at two or more of the following positions may be employed: over the semiconductor 406a, under the semiconductor 406a, over the semiconductor 406c, and under the semiconductor 406c.

For the semiconductor 506 and the semiconductor 606, the description of the semiconductor 406 is referred to.

### <Semiconductor Device>

An example of a semiconductor device of one embodiment of the present invention is described below.

### <Circuit>

An example of a circuit including a transistor of one embodiment of the present invention is described below.

### <CMOS Inverter>

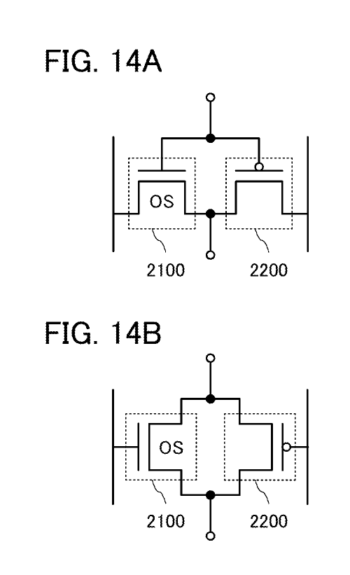

A circuit diagram in FIG. 14A shows a configuration of a so-called CMOS inverter in which a p-channel transistor 2200 and an n-channel transistor 2100 are connected to each other in series and in which gates of them are connected to each other.

### <Structure 1 of Semiconductor Device>

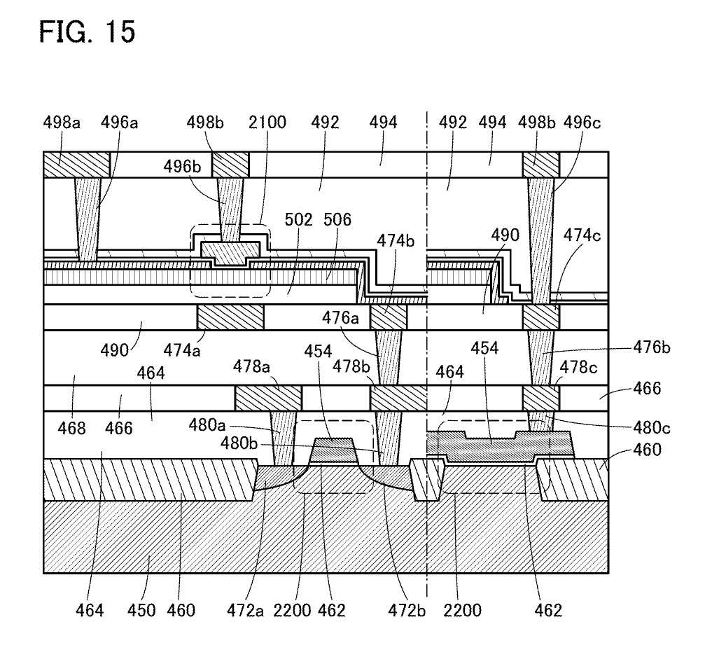

FIG. 15 is a cross-sectional view of the semiconductor device of FIG. 14A. The semiconductor device shown in FIG. 15 includes the transistor 2200 and the transistor 2100. The transistor 2100 is placed above the transistor 2200. Although an example where the transistor shown in FIGS. 8A and 8B is used as the transistor 2100 is shown, a semiconductor device of one embodiment of the present invention is not limited thereto. For example, the transistor shown in FIGS. 3A and 3B can be used as the transistor 2100. Therefore, the description regarding the above-mentioned transistors is referred to for the transistor 2100 as appropriate.

The transistor 2200 shown in FIG. 15 is a transistor using a semiconductor substrate 450. The transistor 2200 includes a region 472a in the semiconductor substrate 450, a region 472b in the semiconductor substrate 450, an insulator 462, and a conductor 454.

In the transistor 2200, the regions 472a and 472b have functions of a source region and a drain region. The insulator 462 has a function of a gate insulator. The conductor 454 has a function of a gate electrode. Therefore, the resistance of a channel formation region can be controlled by a potential applied to the conductor 454. In other words, conduction or non-conduction between the region 472a and the region 472b can be controlled by the potential applied to the conductor 454.

For the semiconductor substrate 450, a single-material semiconductor substrate of silicon, germanium, or the like or a compound semiconductor substrate of silicon carbide, silicon germanium, gallium arsenide, indium phosphide, zinc oxide, gallium oxide, or the like may be used, for example. A single crystal silicon substrate is preferably used as the semiconductor substrate 450.

For the semiconductor substrate 450, a semiconductor substrate including impurities imparting n-type conductivity is used. However, a semiconductor substrate including impurities imparting p-type conductivity may be used as the semiconductor substrate 450. In that case, a well including impurities imparting the n-type conductivity may be provided in a region where the transistor 2200 is formed. Alternatively, the semiconductor substrate 450 may be an i-type semiconductor substrate.

A top surface of the semiconductor substrate 450 preferably has a (110) plane. Thus, on-state characteristics of the transistor 2200 can be improved.

The regions 472a and 472b are regions including impurities imparting the p-type conductivity. Accordingly, the transistor 2200 has a structure of a p-channel transistor.

Note that the transistor 2200 is separated from an adjacent transistor by a region 460 and the like. The region 460 is an insulating region.

The semiconductor device shown in FIG. 15 includes an insulator 464, an insulator 466, an insulator 468, a conductor 480a, a conductor 480b, a conductor 480c, a conductor 478a, a conductor 478b, a conductor 478c, a conductor 476a, a conductor 476b, a conductor 474a, a conductor 474b, a conductor 496a, a conductor 496b, a conductor 496c, a conductor 498a, a conductor 498b, an insulator 490, an insulator 492, and an insulator 494.

The insulator 464 is placed over the transistor 2200. The insulator 466 is placed over the insulator 464. The insulator 468 is placed over the insulator 466. The insulator 490 is placed over the insulator 468. The transistor 2100 is placed over the insulator 490. The insulator 492 is placed over the transistor 2100. The insulator 494 is placed over the insulator 492.

The insulator 464 includes an opening reaching the region 472a, an opening reaching the region 472b, and an opening reaching the conductor 454, in which the conductor 480a, the conductor 480b, and the conductor 480c are embedded, respectively.

In addition, the insulator 466 includes an opening reaching the conductor 480a, an opening reaching the conductor 480b, and an opening reaching the conductor 480c, in which the conductor 478a, the conductor 478b, and the conductor 478c are embedded, respectively.

In addition, the insulator 468 includes an opening reaching the conductor 478b and an opening reaching the conductor 478c, in which the conductor 476a and the conductor 476b are embedded, respectively.

In addition, the insulator 490 includes an opening overlapping with a channel formation region of the transistor 2100, an opening reaching the conductor 476a, and an opening reaching the conductor 476b, in which the conductor 474a, the conductor 474b, and the conductor 474c are embedded, respectively.

The conductor 474a may have a function of a gate electrode of the transistor 2100. Alternatively, the electrical characteristics of the transistor 2100, such as the threshold voltage, may be controlled by application of a predetermined potential to the conductor 474a, for example. The conductor 474a may be electrically connected to the conductor 404 having a function of the gate electrode of the transistor 2100, for example. In that case, on-state current of the transistor 2100 can be increased. Furthermore, a punch-through phenomenon can be suppressed; thus, the electrical characteristics of the transistor 2100 in a saturation region can be stable. The conductor 474b is in contact with one of a source electrode and a drain electrode of the transistor 2100.

In addition, the insulator 492 includes an opening reaching the other of the source electrode and the drain electrode of the transistor 2100, an opening reaching the gate electrode of the transistor 2100, and an opening reaching the conductor 474c, in which the conductor 496a, the conductor 496b, and the conductor 496c are embedded, respectively. Note that in some cases, each opening is provided through a component(s) of the transistor 2100 or the like.

In addition, the insulator 494 includes an opening reaching the conductor 496a, an opening reaching the conductor 496b, and an opening reaching the conductor 496c, in which the conductor 498a or the conductor 498b is embedded.

The insulators 464, 466, 468, 490, 492, and 494 may each be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. The insulator 401 may be formed using, for example, aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

The insulator that has a function of blocking oxygen and impurities such as hydrogen is preferably included in at least one of the insulators 464, 466, 468, 490, 492, and 494. When an insulator that has a function of blocking oxygen and impurities such as hydrogen is placed near the transistor 2100, the electrical characteristics of the transistor 2100 can be stable.

An insulator with a function of blocking oxygen and impurities such as hydrogen may be formed to have, for example, a single-layer structure or a stacked-layer structure including an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum.

Each of the conductor 480a, the conductor 480b, the conductor 480c, the conductor 478a, the conductor 478b, the conductor 478c, the conductor 476a, the conductor 476b, the conductor 474a, the conductor 474b, the conductor 496a, the conductor 496b, the conductor 496c, the conductor 498a, and the conductor 498b may be formed to have, for example, a single-layer structure or a stacked-layer structure including a conductor containing one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten. An alloy or a compound containing the above element may be used, for example, and a conductor containing aluminum, a conductor containing copper and titanium, a conductor containing copper and manganese, a conductor containing indium, tin, and oxygen, a conductor containing titanium and nitrogen, or the like may be used.

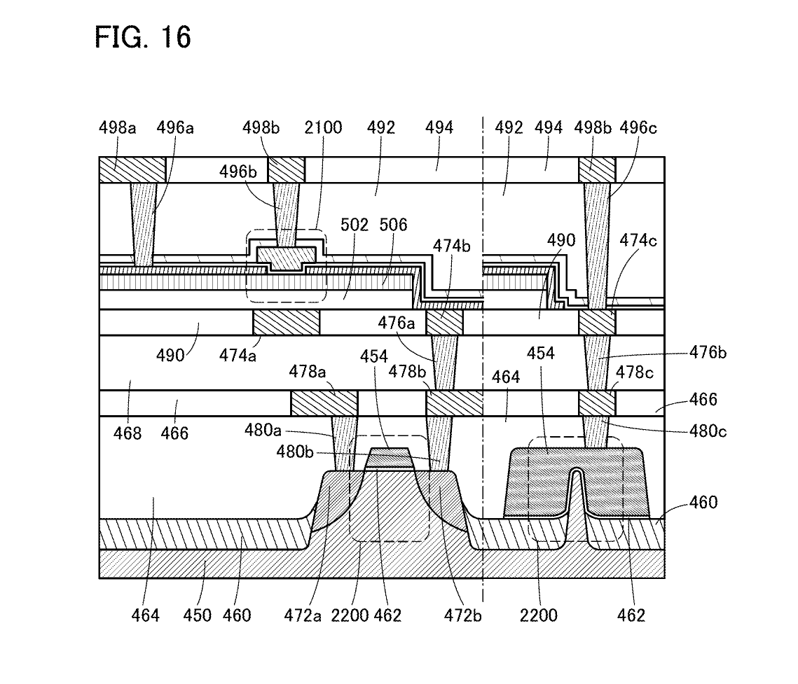

Note that a semiconductor device in FIG. 16 is the same as the semiconductor device in FIG. 15 except a structure of the transistor 2200. Therefore, the description of the semiconductor device in FIG. 15 is referred to for the semiconductor device in FIG. 16. In the semiconductor device in FIG. 16, the transistor 2200 is a FIN-type transistor. The effective channel width is increased in the FIN-type transistor 2200, whereby the on-state characteristics of the transistor 2200 can be improved. In addition, since contribution of the electric field of the gate electrode can be increased, the off-state characteristics of the transistor 2200 can be improved.

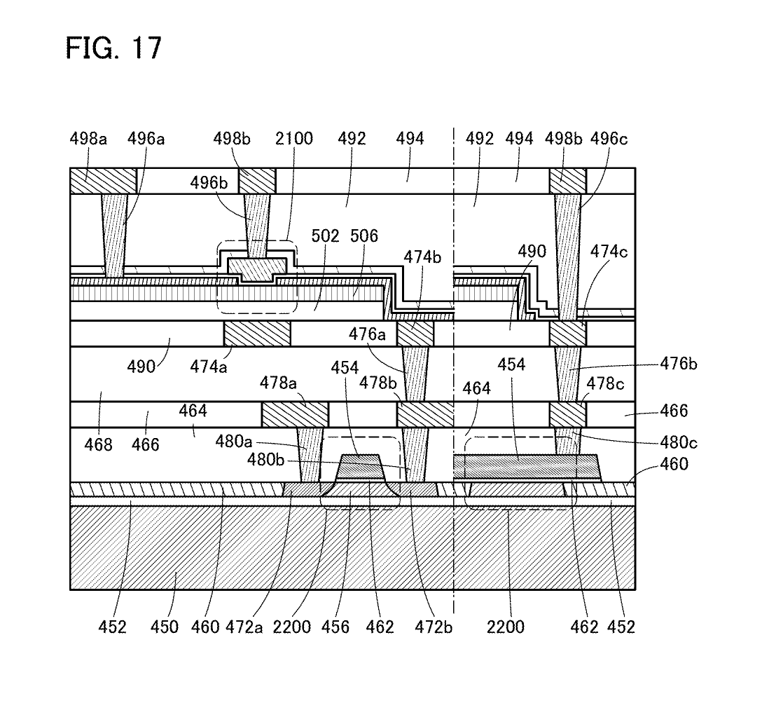

Note that a semiconductor device in FIG. 17 is the same as the semiconductor device in FIG. 15 except a structure of the transistor 2200. Therefore, the description of the semiconductor device in FIG. 15 is referred to for the semiconductor device in FIG. 17. In the semiconductor device in FIG. 17, the transistor 2200 is formed using an SOI substrate. In the structure in FIG. 17, a region 456 is separated from the semiconductor substrate 450 with an insulator 452 provided therebetween. Since the SOI substrate is used, a punch-through phenomenon and the like can be suppressed; thus, the off-state characteristics of the transistor 2200 can be improved. Note that the insulator 452 can be formed by turning part of the semiconductor substrate 450 into an insulator. For example, silicon oxide can be used as the insulator 452.

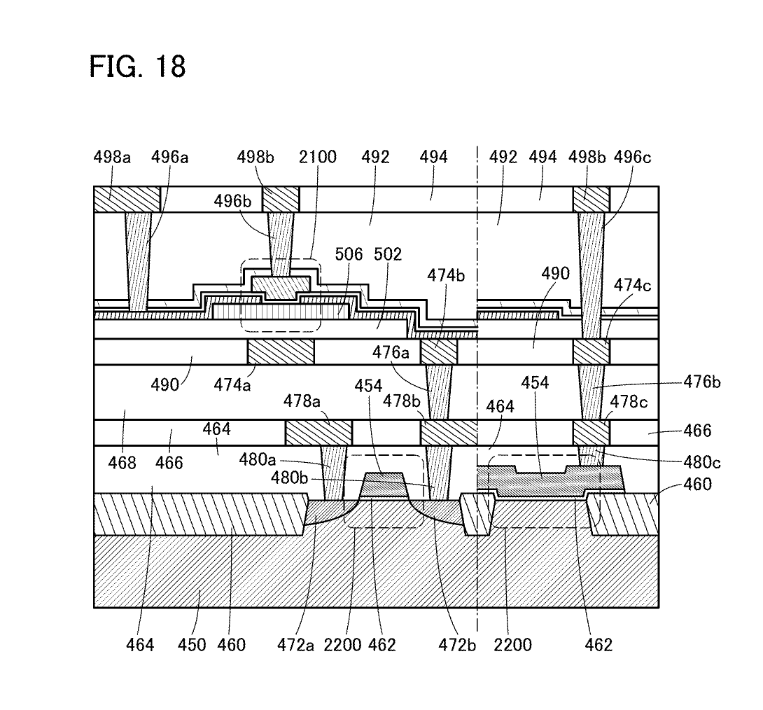

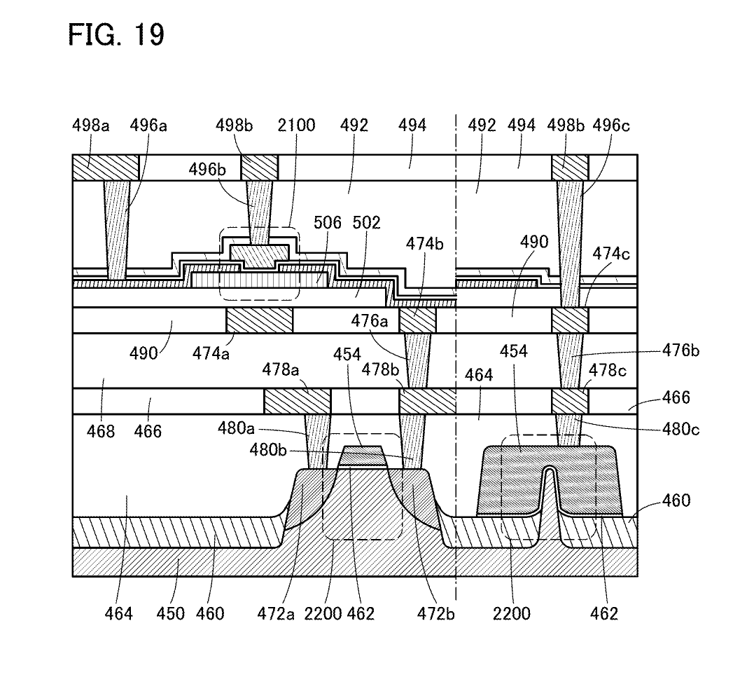

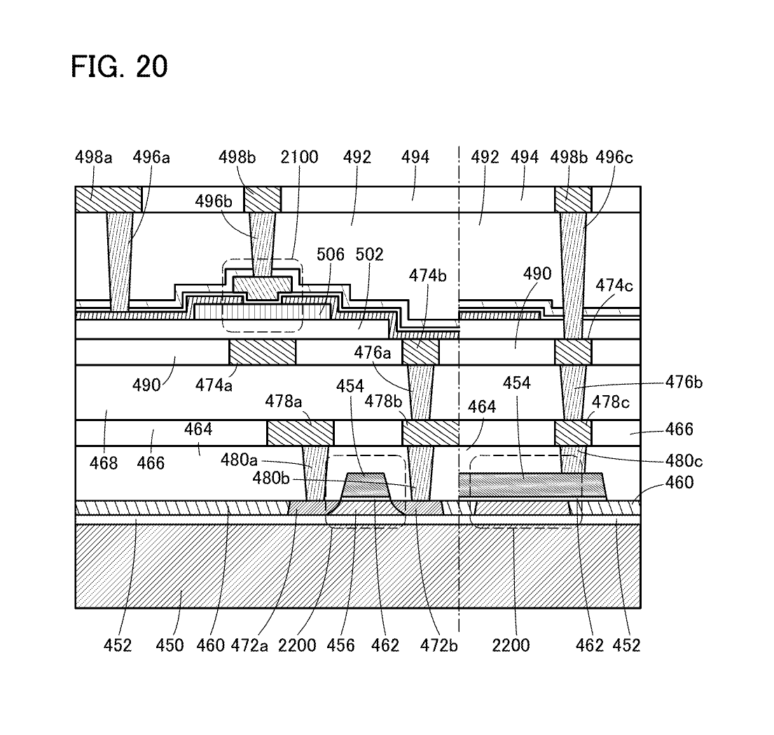

Note that in each of the semiconductor devices illustrated in FIGS. 15, 16, and 17, an end portion of the semiconductor 506 and an end portion of the insulator 502 are substantially aligned with each other in the transistor 2100. With such a shape, the area occupied by an element, a wiring, and the like of a miniature semiconductor device can be reduced in some cases. Note that the structure of the semiconductor device of one embodiment of the present invention is not limited to this. For example, a structure may be employed in which the end portion of the semiconductor 506 and that of the insulator 502 are not aligned with each other in the transistor 2100 as illustrated in FIGS. 18, 19, and 20.

In each of the semiconductor devices shown in FIGS. 15 to 20, a p-channel transistor is formed utilizing a semiconductor substrate, and an n-channel transistor is formed above that; therefore, an occupation area of the element can be reduced. That is, the integration degree of the semiconductor device can be improved. In addition, the manufacturing process can be simplified compared to the case where an n-channel transistor and a p-channel transistor are formed utilizing the same semiconductor substrate; therefore, the productivity of the semiconductor device can be increased. Moreover, the yield of the semiconductor device can be improved. For the p-channel transistor, some complicated steps such as formation of lightly doped drain (LDD) regions, formation of a shallow trench structure, or distortion design can be omitted in some cases. Therefore, the productivity and yield of the semiconductor device can be increased in some cases, compared to a semiconductor device where an n-channel transistor is formed utilizing the semiconductor substrate.

### <CMOS Analog Switch>

A circuit diagram in FIG. 14B shows a configuration in which sources of the transistors 2100 and 2200 are connected to each other and drains of the transistors 2100 and 2200 are connected to each other. With such a configuration, the transistors can function as a so-called CMOS analog switch.

### <Memory Device 1>

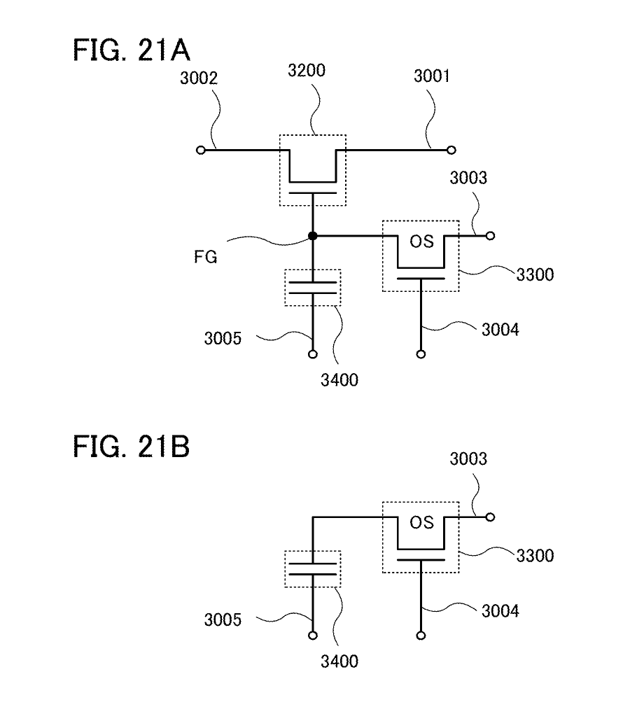

An example of a semiconductor device (memory device) which includes the transistor of one embodiment of the present invention, which can retain stored data even when not powered, and which has an unlimited number of write cycles is shown in FIGS. 21A and 21B.

The semiconductor device illustrated in FIG. 21A includes a transistor 3200 using a first semiconductor, a transistor 3300 using a second semiconductor, and a capacitor 3400. Note that any of the above-described transistors can be used as the transistor 3300.

Note that the transistor 3300 is preferably a transistor with a low off-state current. For example, a transistor using an oxide semiconductor can be used as the transistor 3300. Since the off-state current of the transistor 3300 is low, stored data can be retained for a long period at a predetermined node of the semiconductor device. In other words, power consumption of the semiconductor device can be reduced because refresh operation becomes unnecessary or the frequency of refresh operation can be extremely low.

In FIG. 21A, a first wiring 3001 is electrically connected to a source of the transistor 3200. A second wiring 3002 is electrically connected to a drain of the transistor 3200. A third wiring 3003 is electrically connected to one of the source and the drain of the transistor 3300. A fourth wiring 3004 is electrically connected to the gate of the transistor 3300. The gate of the transistor 3200 and the other of the source and the drain of the transistor 3300 are electrically connected to the one electrode of the capacitor 3400. A fifth wiring 3005 is electrically connected to the other electrode of the capacitor 3400.

The semiconductor device in FIG. 21A has a feature that the potential of the gate of the transistor 3200 can be retained, and thus enables writing, retaining, and reading of data as follows.

Writing and retaining of data are described. First, the potential of the fourth wiring 3004 is set to a potential at which the transistor 3300 is in a conductive state, so that the transistor 3300 is in a conductive state. Accordingly, the potential of the third wiring 3003 is supplied to a node FG where the gate of the transistor 3200 and the one electrode of the capacitor 3400 are electrically connected to each other. That is, a predetermined charge is supplied to the gate of the transistor 3200 (writing). Here, one of two kinds of charges providing different potential levels (hereinafter referred to as a low-level charge and a high-level charge) is supplied. After that, the potential of the fourth wiring 3004 is set to a potential at which the transistor 3300 is in a non-conductive state, so that the transistor 3300 is in the non-conductive state. Thus, the charge is held at the node FG (retaining).

Since the off-state current of the transistor 3300 is low, the charge of the node FG is retained for a long time.

Next, reading of data is described. An appropriate potential (a reading potential) is supplied to the fifth wiring 3005 while a predetermined potential (a constant potential) is supplied to the first wiring 3001, whereby the potential of the second wiring 3002 varies depending on the amount of charge retained in the node FG. This is because in the case of using an n-channel transistor as the transistor 3200, an apparent threshold voltage Vₜₕ_{_{—}}_{H} at the time when the high-level charge is given to the gate of the transistor 3200 is lower than an apparent threshold voltage Vₜₕ_{_{—}}_{L} at the time when the low-level charge is given to the gate of the transistor 3200. Here, an apparent threshold voltage refers to the potential of the fifth wiring 3005 which is needed to make the transistor 3200 be in “a conductive state.” Thus, the potential of the fifth wiring 3005 is set to a potential V₀ which is between Vₜₕ_{_{—}}_{H} and Vₜₕ_{_{—}}_{L}, whereby charge supplied to the node FG can be determined. For example, in the case where the high-level charge is supplied to the node FG in writing and the potential of the fifth wiring 3005 is V₀ (>Vₜₕ_{_{—}}_{H}), the transistor 3200 is brought into “the conductive state.” On the other hand, in the case where the low-level charge is supplied to the node FG in writing, even when the potential of the fifth wiring 3005 is V₀ (<Vₜₕ_{_{—}}_{L}), the transistor 3200 still remains in “the non-conductive state.” Thus, the data retained in the node FG can be read by determining the potential of the second wiring 3002.

Note that in the case where memory cells are arrayed, it is necessary that data of a desired memory cell be read in read operation. In the case where data of the other memory cells is not read, the fifth wiring 3005 may be supplied with a potential at which the transistor 3200 is in “a non-conductive state” regardless of the charge supplied to the node FG, that is, a potential lower than Vₜₕ_{_{—}}_{H}. Alternatively, the fifth wiring 3005 may be supplied with a potential at which the transistor 3200 is brought into “a conductive state” regardless of the charge supplied to the node FG, that is, a potential higher than Vₜₕ_{_{—}}_{L}.

### <Structure 2 of Semiconductor Device>

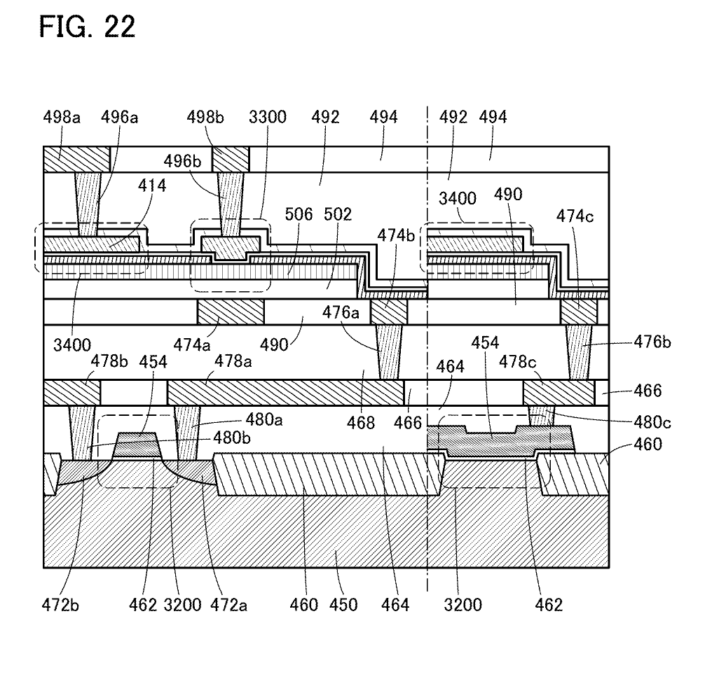

FIG. 22 is a cross-sectional view of the semiconductor device of FIG. 21A. The semiconductor device shown in FIG. 22 includes the transistor 3200, the transistor 3300, and the capacitor 3400. The transistor 3300 and the capacitor 3400 are placed above the transistor 3200. Note that for the transistor 3300, the description of the above transistor 2100 is referred to. Furthermore, for the transistor 3200, the description of the transistor 2200 in FIG. 15 is referred to. Note that although the transistor 2200 is illustrated as a p-channel transistor in FIG. 15, the transistor 3200 may be an n-channel transistor.

The source or drain of the transistor 3200 is electrically connected to one of a source electrode and a drain electrode of the transistor 3300 through the conductor 480a, the conductor 478a, the conductor 476a, and the conductor 474b. A gate electrode of the transistor 3200 is electrically connected to the other of the source electrode and the drain electrode of the transistor 3300 through the conductor 480c, the conductor 478c, the conductor 476b, and the conductor 474c.

The capacitor 3400 includes an electrode electrically connected to the other of the source electrode and the drain electrode of the transistor 3300, a conductor 414, and an insulator. In some cases, it is preferable that the insulator be a layer formed by the same step as a gate insulator of the transistor 3300 because productivity can be improved. In some cases, it is preferable that the conductor 414 be a layer formed by the same step as a gate electrode of the transistor 3300 because productivity can be improved.

For the structures of other components, the description of FIG. 15 can be referred to.

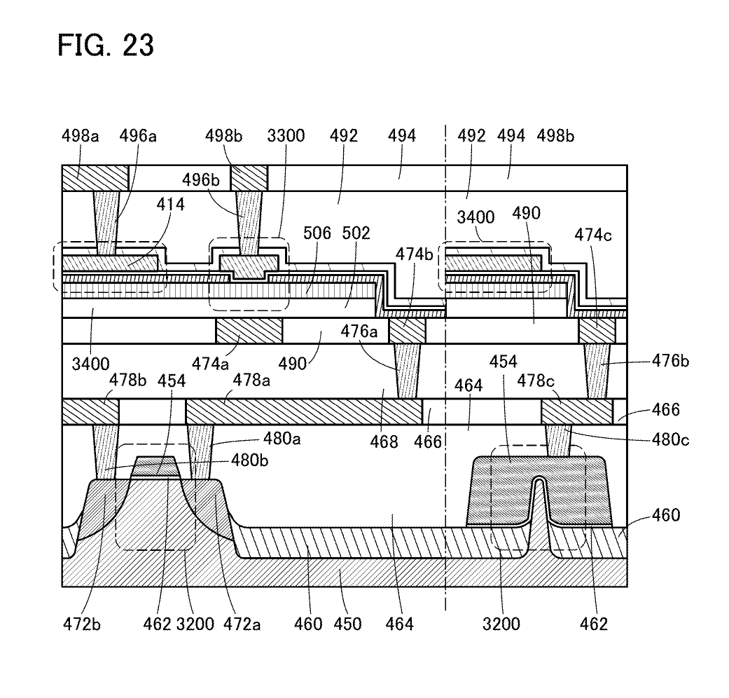

Note that a semiconductor device in FIG. 23 is the same as the semiconductor device in FIG. 22 except a structure of the transistor 3200. Therefore, the description of the semiconductor device in FIG. 22 is referred to for the semiconductor device in FIG. 23. Specifically, in the semiconductor device in FIG. 23, the transistor 3200 is a FIN-type transistor. For the FIN-type transistor 3200, the description of the transistor 2200 in FIG. 16 is referred to. Note that although the transistor 2200 is illustrated as a p-channel transistor in FIG. 16, the transistor 3200 may be an n-channel transistor.

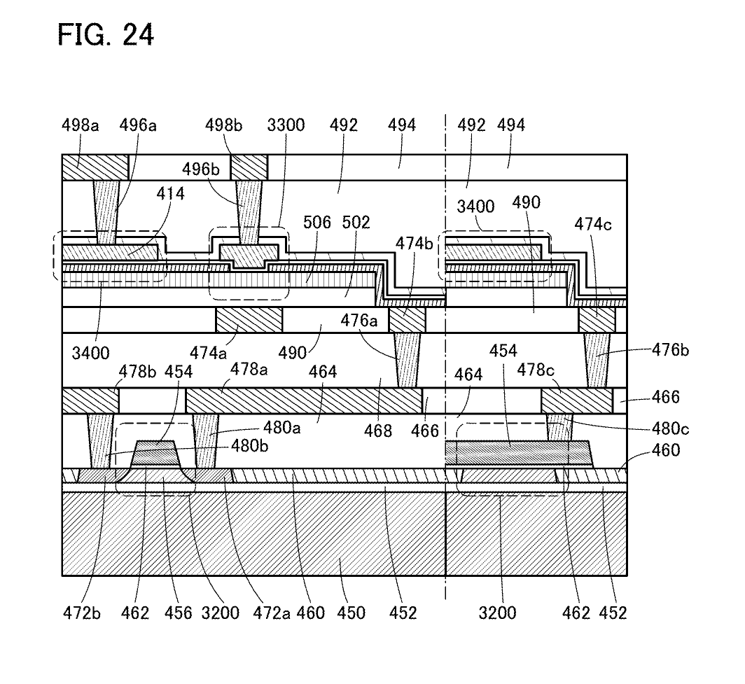

A semiconductor device in FIG. 24 is the same as the semiconductor device in FIG. 22 except a structure of the transistor 3200. Therefore, the description of the semiconductor device in FIG. 22 is referred to for the semiconductor device in FIG. 24. Specifically, in the semiconductor device in FIG. 24, the transistor 3200 is provided in the semiconductor substrate 450 that is an SOI substrate. For the transistor 3200, which is provided in the semiconductor substrate 450 that is an SOI substrate, the description of the transistor 2200 in FIG. 17 is referred to. Note that although the transistor 2200 is illustrated as a p-channel transistor in FIG. 17, the transistor 3200 may be an n-channel transistor.

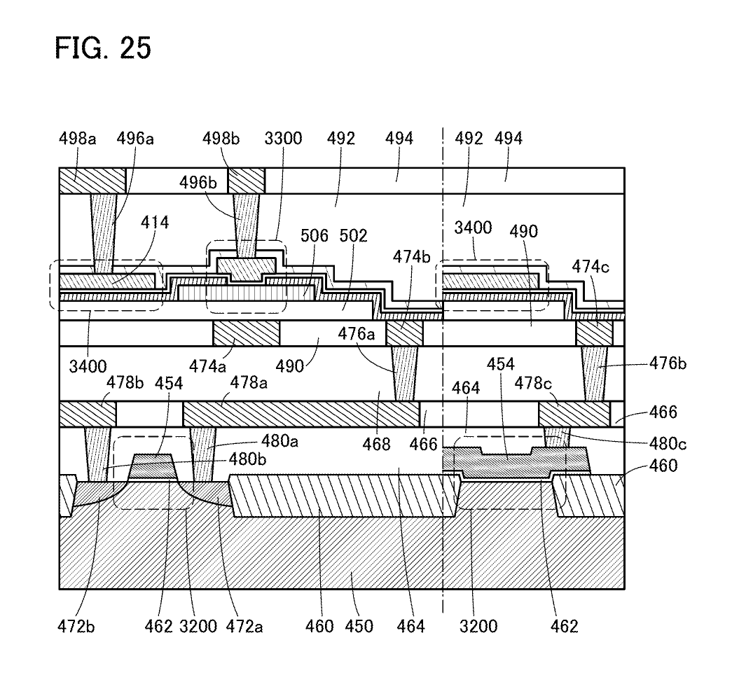

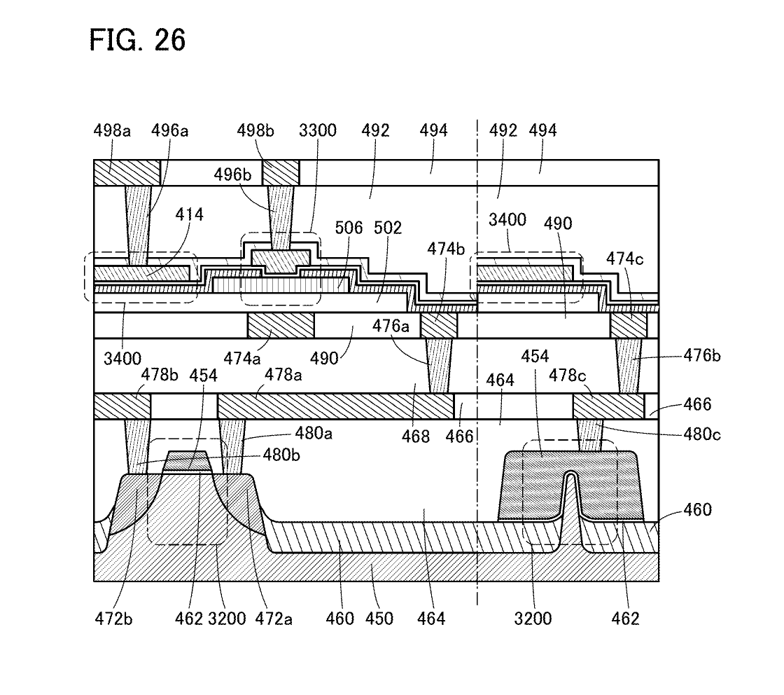

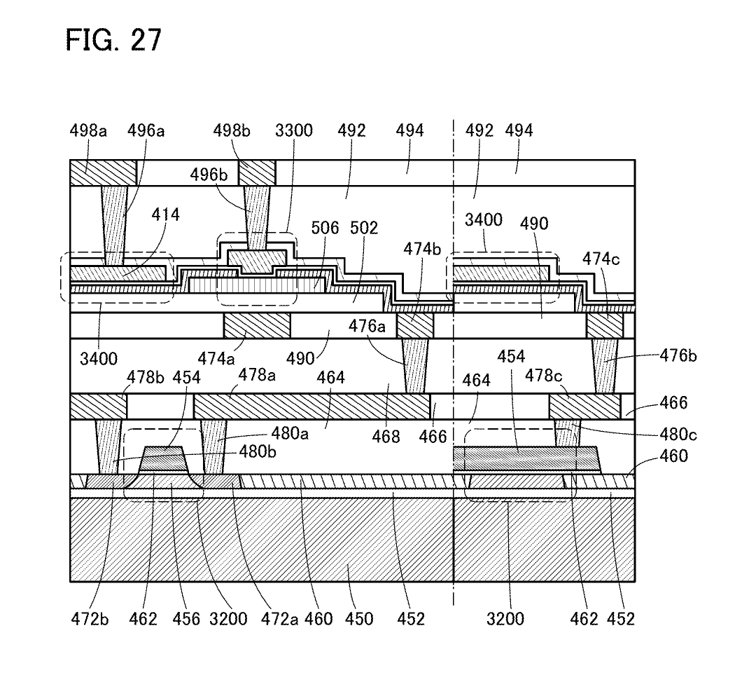

Note that in each of the semiconductor devices illustrated in FIGS. 22, 23, and 24, an end portion of the semiconductor 506 and an end portion of the insulator 502 are substantially aligned with each other in the transistor 3300. With such a shape, the area occupied by an element, a wiring, and the like of a miniature semiconductor device can be reduced in some cases. Note that the structure of the semiconductor device of one embodiment of the present invention is not limited to this. For example, a structure may be employed in which the end portion of the semiconductor 506 and that of the insulator 502 are not aligned with each other in the transistor 3300 as illustrated in FIGS. 25, 26, and 27.

### <Memory Device 2>

The semiconductor device in FIG. 21B is different form the semiconductor device in FIG. 21A in that the transistor 3200 is not provided. Also in this case, data can be written and retained in a manner similar to that of the semiconductor device in FIG. 21A.

Reading of data in the semiconductor device in FIG. 21B is described. When the transistor 3300 is brought into a conductive state, the third wiring 3003 which is in a floating state and the capacitor 3400 are brought into conduction, and the charge is redistributed between the third wiring 3003 and the capacitor 3400. As a result, the potential of the third wiring 3003 is changed. The amount of change in potential of the third wiring 3003 varies depending on the potential of the one electrode of the capacitor 3400 (or the charge accumulated in the capacitor 3400).

For example, the potential of the third wiring 3003 after the charge redistribution is (C_{B}×V_{B0}+C×V)/(C_{B}+C), where V is the potential of the one electrode of the capacitor 3400, C is the capacitance of the capacitor 3400, C_{B} is the capacitance component of the third wiring 3003, and V_{B0} is the potential of the third wiring 3003 before the charge redistribution. Thus, it can be found that, assuming that the memory cell is in either of two states in which the potential of the one electrode of the capacitor 3400 is V₁ and V₀ (V₁>V₀), the potential of the third wiring 3003 in the case of retaining the potential V₁ (=(C_{B}×V_{B0}+C×V₁)/(C_{B}+C)) is higher than the potential of the third wiring 3003 in the case of retaining the potential V₀ (=(C_{B}×V_{B0}+C×V₀)/(C_{B}+C).

Then, by comparing the potential of the third wiring 3003 with a predetermined potential, data can be read.

In this case, a transistor including the first semiconductor may be used for a driver circuit for driving a memory cell, and a transistor including the second semiconductor may be stacked over the driver circuit as the transistor 3300.

When including a transistor using an oxide semiconductor and having a low off-state current, the semiconductor device described above can retain stored data for a long time. In other words, power consumption of the semiconductor device can be reduced because refresh operation becomes unnecessary or the frequency of refresh operation can be extremely low. Moreover, stored data can be retained for a long time even when power is not supplied (note that a potential is preferably fixed).

In the semiconductor device, high voltage is not needed for writing data and deterioration of elements is less likely to occur. Unlike in a conventional nonvolatile memory, for example, it is not necessary to inject and extract electrons into and from a floating gate; thus, a problem such as deterioration of an insulator is not caused. That is, the semiconductor device of one embodiment of the present invention does not have a limit on the number of times data can be rewritten, which is a problem of a conventional nonvolatile memory, and the reliability thereof is drastically improved. Furthermore, data is written depending on the conductive/non-conductive state of the transistor, whereby high-speed operation can be achieved.

### <CPU>

A CPU including a semiconductor device such as any of the above-described transistors or the above-described memory device is described below.

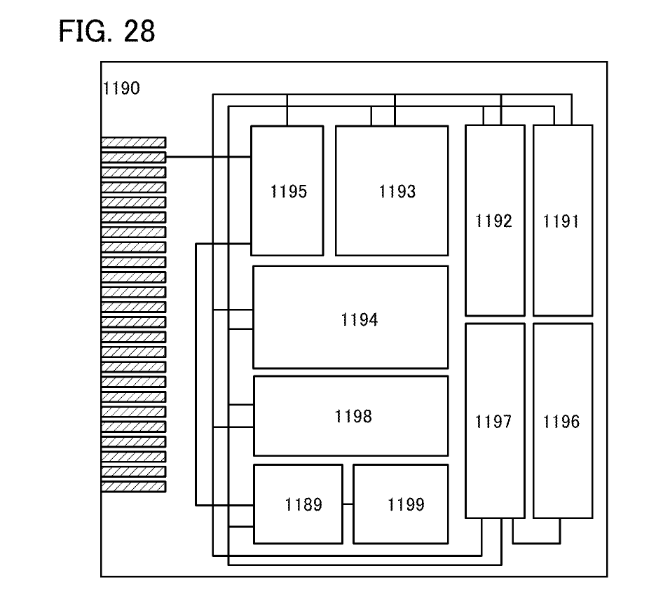

FIG. 28 is a block diagram illustrating a configuration example of a CPU including any of the above-described transistors as a component.

The CPU illustrated in FIG. 28 includes, over a substrate 1190, an arithmetic logic unit (ALU) 1191, an ALU controller 1192, an instruction decoder 1193, an interrupt controller 1194, a timing controller 1195, a register 1196, a register controller 1197, a bus interface 1198, a rewritable ROM 1199, and a ROM interface 1189. A semiconductor substrate, an SOI substrate, a glass substrate, or the like is used as the substrate 1190. The ROM 1199 and the ROM interface 1189 may be provided over a separate chip. Needless to say, the CPU in FIG. 28 is just an example in which the configuration has been simplified, and an actual CPU may have a variety of configurations depending on the application. For example, the CPU may have the following configuration: a structure including the CPU illustrated in FIG. 28 or an arithmetic circuit is considered as one core; a plurality of the cores are included; and the cores operate in parallel. The number of bits that the CPU can process in an internal arithmetic circuit or in a data bus can be 8, 16, 32, or 64, for example.

An instruction that is input to the CPU through the bus interface 1198 is input to the instruction decoder 1193 and decoded therein, and then, input to the ALU controller 1192, the interrupt controller 1194, the register controller 1197, and the timing controller 1195.

The ALU controller 1192, the interrupt controller 1194, the register controller 1197, and the timing controller 1195 conduct various controls in accordance with the decoded instruction. Specifically, the ALU controller 1192 generates signals for controlling the operation of the ALU 1191. While the CPU is executing a program, the interrupt controller 1194 judges an interrupt request from an external input/output device or a peripheral circuit on the basis of its priority or a mask state, and processes the request. The register controller 1197 generates an address of the register 1196, and reads/writes data from/to the register 1196 in accordance with the state of the CPU.

The timing controller 1195 generates signals for controlling operation timings of the ALU 1191, the ALU controller 1192, the instruction decoder 1193, the interrupt controller 1194, and the register controller 1197. For example, the timing controller 1195 includes an internal clock generator for generating an internal clock signal based on a reference clock signal, and supplies the internal clock signal to the above circuits.

In the CPU illustrated in FIG. 28, a memory cell is provided in the register 1196. For the memory cell of the register 1196, any of the above-described transistors, the above-described memory device, or the like can be used.

In the CPU illustrated in FIG. 28, the register controller 1197 selects operation of retaining data in the register 1196 in accordance with an instruction from the ALU 1191. That is, the register controller 1197 selects whether data is retained by a flip-flop or by a capacitor in the memory cell included in the register 1196. When data retaining by the flip-flop is selected, a power supply voltage is supplied to the memory cell in the register 1196. When data retaining by the capacitor is selected, the data is rewritten in the capacitor, and supply of power supply voltage to the memory cell in the register 1196 can be stopped.

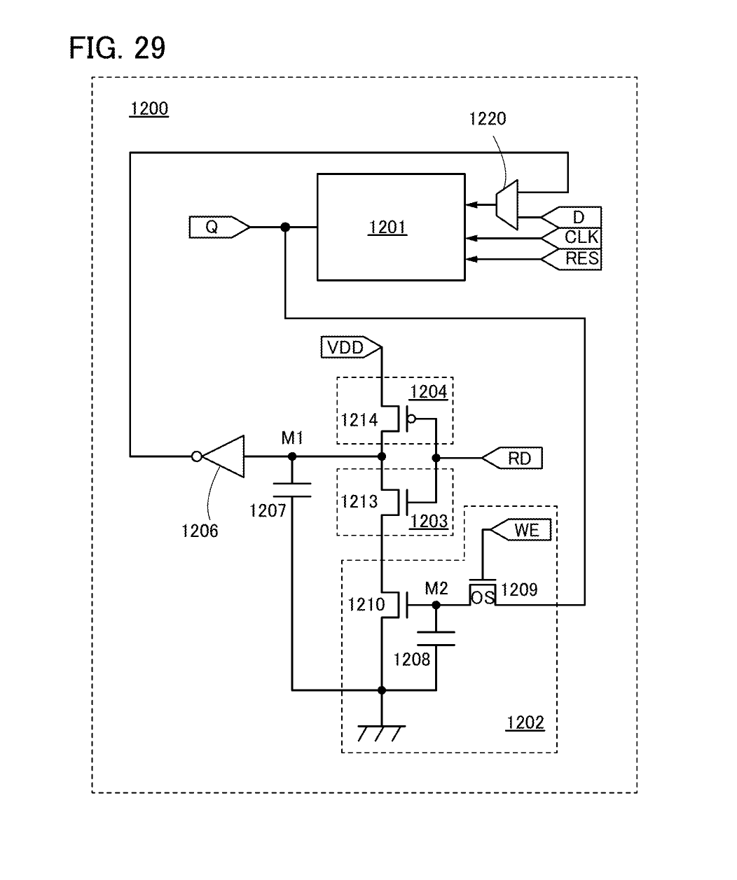

FIG. 29 is an example of a circuit diagram of a memory element 1200 that can be used as the register 1196. The memory element 1200 includes a circuit 1201 in which stored data is volatile when power supply is stopped, a circuit 1202 in which stored data is nonvolatile even when power supply is stopped, a switch 1203, a switch 1204, a logic element 1206, a capacitor 1207, and a circuit 1220 having a selecting function. The circuit 1202 includes a capacitor 1208, a transistor 1209, and a transistor 1210. Note that the memory element 1200 may further include another element such as a diode, a resistor, or an inductor, as needed.

Here, the above-described memory device can be used as the circuit 1202. When supply of a power supply voltage to the memory element 1200 is stopped, GND (0 V) or a potential at which the transistor 1209 in the circuit 1202 is turned off continues to be input to a gate of the transistor 1209. For example, the gate of the transistor 1209 is grounded through a load such as a resistor.

Shown here is an example in which the switch 1203 is a transistor 1213 having one conductivity type (e.g., an n-channel transistor) and the switch 1204 is a transistor 1214 having a conductivity type opposite to the one conductivity type (e.g., a p-channel transistor). A first terminal of the switch 1203 corresponds to one of a source and a drain of the transistor 1213, a second terminal of the switch 1203 corresponds to the other of the source and the drain of the transistor 1213, and conduction or non-conduction between the first terminal and the second terminal of the switch 1203 (i.e., the conductive/non-conductive state of the transistor 1213) is selected by a control signal RD input to a gate of the transistor 1213. A first terminal of the switch 1204 corresponds to one of a source and a drain of the transistor 1214, a second terminal of the switch 1204 corresponds to the other of the source and the drain of the transistor 1214, and conduction or non-conduction between the first terminal and the second terminal of the switch 1204 (i.e., the conductive/non-conductive state of the transistor 1214) is selected by the control signal RD input to a gate of the transistor 1214.

One of a source and a drain of the transistor 1209 is electrically connected to one of a pair of electrodes of the capacitor 1208 and a gate of the transistor 1210. Here, the connection portion is referred to as a node M2. One of a source and a drain of the transistor 1210 is electrically connected to a line which can supply a low power supply potential (e.g., a GND line), and the other thereof is electrically connected to the first terminal of the switch 1203 (the one of the source and the drain of the transistor 1213). The second terminal of the switch 1203 (the other of the source and the drain of the transistor 1213) is electrically connected to the first terminal of the switch 1204 (the one of the source and the drain of the transistor 1214). The second terminal of the switch 1204 (the other of the source and the drain of the transistor 1214) is electrically connected to a line which can supply a power supply potential VDD. The second terminal of the switch 1203 (the other of the source and the drain of the transistor 1213), the first terminal of the switch 1204 (the one of the source and the drain of the transistor 1214), an input terminal of the logic element 1206, and one of a pair of electrodes of the capacitor 1207 are electrically connected to each other. Here, the connection portion is referred to as a node M1. The other of the pair of electrodes of the capacitor 1207 can be supplied with a constant potential. For example, the other of the pair of electrodes of the capacitor 1207 can be supplied with a low power supply potential (e.g., GND) or a high power supply potential (e.g., VDD). The other of the pair of electrodes of the capacitor 1207 is electrically connected to the line which can supply a low power supply potential (e.g., a GND line). The other of the pair of electrodes of the capacitor 1208 can be supplied with a constant potential. For example, the other of the pair of electrodes of the capacitor 1208 can be supplied with the low power supply potential (e.g., GND) or the high power supply potential (e.g., VDD). The other of the pair of electrodes of the capacitor 1208 is electrically connected to the line which can supply a low power supply potential (e.g., a GND line).

The capacitor 1207 and the capacitor 1208 are not necessarily provided as long as the parasitic capacitance of the transistor, the wiring, or the like is actively utilized.

A control signal WE is input to the gate of the transistor 1209. As for each of the switch 1203 and the switch 1204, a conductive state or a non-conductive state between the first terminal and the second terminal is selected by the control signal RD which is different from the control signal WE. When the first terminal and the second terminal of one of the switches are in the conductive state, the first terminal and the second terminal of the other of the switches are in the non-conductive state.

A signal corresponding to data retained in the circuit 1201 is input to the other of the source and the drain of the transistor 1209. FIG. 29 illustrates an example in which a signal output from the circuit 1201 is input to the other of the source and the drain of the transistor 1209. The logic value of a signal output from the second terminal of the switch 1203 (the other of the source and the drain of the transistor 1213) is inverted by the logic element 1206, and the inverted signal is input to the circuit 1201 through the circuit 1220.

In the example of FIG. 29, a signal output from the second terminal of the switch 1203 (the other of the source and the drain of the transistor 1213) is input to the circuit 1201 through the logic element 1206 and the circuit 1220; however, one embodiment of the present invention is not limited thereto. The signal output from the second terminal of the switch 1203 (the other of the source and the drain of the transistor 1213) may be input to the circuit 1201 without its logic value being inverted. For example, in the case where the circuit 1201 includes a node in which a signal obtained by inversion of the logic value of a signal input from the input terminal is retained, the signal output from the second terminal of the switch 1203 (the other of the source and the drain of the transistor 1213) can be input to the node.

In FIG. 29, the transistors included in the memory element 1200 except for the transistor 1209 can each be a transistor in which a channel is formed in a film formed using a semiconductor other than an oxide semiconductor or in the substrate 1190. For example, the transistor can be a transistor whose channel is formed in a silicon film or a silicon substrate. Alternatively, all the transistors in the memory element 1200 may be a transistor in which a channel is formed in an oxide semiconductor. Further alternatively, in the memory element 1200, a transistor in which a channel is formed in an oxide semiconductor may be included besides the transistor 1209, and a transistor in which a channel is formed in a layer formed using a semiconductor other than an oxide semiconductor or in the substrate 1190 can be used for the rest of the transistors.

As the circuit 1201 in FIG. 29, for example, a flip-flop circuit can be used. As the logic element 1206, for example, an inverter or a clocked inverter can be used.

In a period during which the memory element 1200 is not supplied with the power supply voltage, the semiconductor device of one embodiment of the present invention can retain data stored in the circuit 1201 by the capacitor 1208 which is provided in the circuit 1202.

The off-state current of a transistor in which a channel is formed in an oxide semiconductor is extremely low. For example, the off-state current of a transistor in which a channel is formed in an oxide semiconductor is significantly lower than that of a transistor in which a channel is formed in silicon having crystallinity. Thus, when the transistor is used as the transistor 1209, a signal held in the capacitor 1208 is retained for a long time also in a period during which the power supply voltage is not supplied to the memory element 1200. The memory element 1200 can accordingly retain the stored content (data) also in a period during which the supply of the power supply voltage is stopped.

Since the above-described memory element performs pre-charge operation with the switch 1203 and the switch 1204, the time required for the circuit 1201 to retain original data again after the supply of the power supply voltage is restarted can be shortened.

In the circuit 1202, a signal retained by the capacitor 1208 is input to the gate of the transistor 1210. Therefore, after supply of the power supply voltage to the memory element 1200 is restarted, the signal retained by the capacitor 1208 can be converted into the one corresponding to the state (the conductive state or the non-conductive state) of the transistor 1210 to be read from the circuit 1202. Consequently, an original signal can be accurately read even when a potential corresponding to the signal retained by the capacitor 1208 varies to some degree.

By applying the above-described memory element 1200 to a memory device such as a register or a cache memory included in a processor, data in the memory device can be prevented from being lost owing to the stop of the supply of the power supply voltage. Furthermore, shortly after the supply of the power supply voltage is restarted, the memory device can be returned to the same state as that before the power supply is stopped. Therefore, the power supply can be stopped even for a short time in the processor or one or a plurality of logic circuits included in the processor, resulting in lower power consumption.

Although the memory element 1200 is used in a CPU, the memory element 1200 can also be used in an LSI such as a digital signal processor (DSP), a custom LSI, or a programmable logic device (PLD), and a radio frequency identification (RF-ID).

### <Display Device>

The following shows configuration examples of a display device of one embodiment of the present invention.

### [Configuration Example]

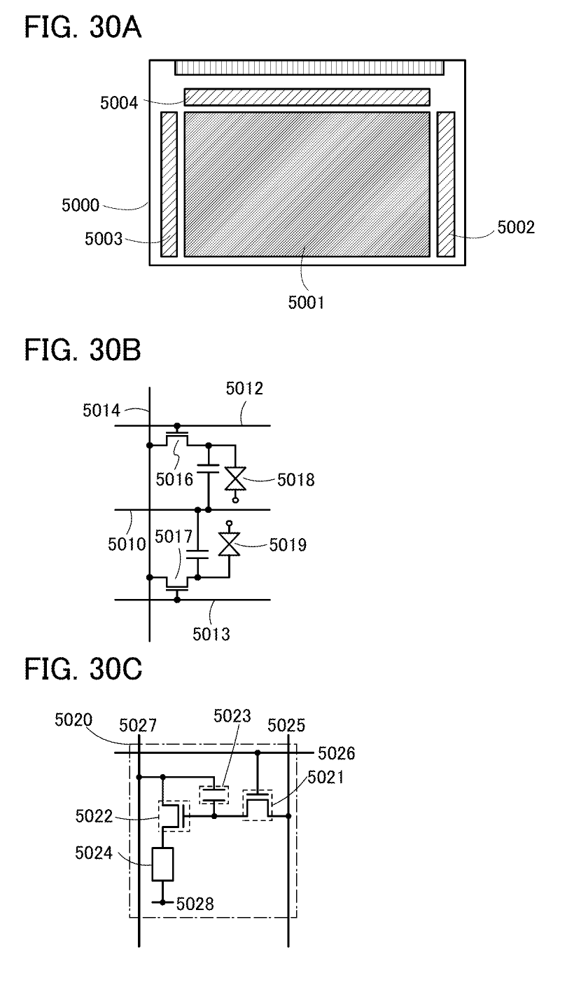

FIG. 30A is a top view of a display device of one embodiment of the present invention. FIG. 30B illustrates a pixel circuit where a liquid crystal element is used for a pixel of a display device of one embodiment of the present invention. FIG. 30C illustrates a pixel circuit where an organic EL element is used for a pixel of a display device of one embodiment of the present invention.

Any of the above-described transistors can be used as a transistor used for the pixel. Here, an example in which an n-channel transistor is used is shown. Note that a transistor manufactured through the same steps as the transistor used for the pixel may be used for a driver circuit. Thus, by using any of the above-described transistors for a pixel or a driver circuit, the display device can have high display quality and/or high reliability.

FIG. 30A illustrates an example of an active matrix display device. A pixel portion 5001, a first scan line driver circuit 5002, a second scan line driver circuit 5003, and a signal line driver circuit 5004 are provided over a substrate 5000 in the display device. The pixel portion 5001 is electrically connected to the signal line driver circuit 5004 through a plurality of signal lines and is electrically connected to the first scan line driver circuit 5002 and the second scan line driver circuit 5003 through a plurality of scan lines. Pixels including display elements are provided in respective regions divided by the scan lines and the signal lines. The substrate 5000 of the display device is electrically connected to a timing control circuit (also referred to as a controller or a control IC) through a connection portion such as a flexible printed circuit (FPC).

The first scan line driver circuit 5002, the second scan line driver circuit 5003, and the signal line driver circuit 5004 are formed over the substrate 5000 where the pixel portion 5001 is formed. Therefore, a display device can be manufactured at cost lower than that in the case where a driver circuit is separately formed. Furthermore, in the case where a driver circuit is separately formed, the number of wiring connections is increased. By providing the driver circuit over the substrate 5000, the number of wiring connections can be reduced. Accordingly, the reliability and/or yield can be improved.

### [Liquid Crystal Display Device]

FIG. 30B illustrates an example of a circuit configuration of the pixel. Here, a pixel circuit which is applicable to a pixel of a VA liquid crystal display device, or the like is illustrated.

This pixel circuit can be applied to a structure in which one pixel includes a plurality of pixel electrodes. The pixel electrodes are connected to different transistors, and the transistors can be driven with different gate signals. Accordingly, signals applied to individual pixel electrodes in a multi-domain pixel can be controlled independently.

A scan line 5012 of a transistor 5016 and a scan line 5013 of a transistor 5017 are separated so that different gate signals can be supplied thereto. In contrast, a signal line 5014 is shared by the transistors 5016 and 5017. Any of the above-described transistors can be used as appropriate as each of the transistors 5016 and 5017. Thus, the liquid crystal display device can have a high display quality and/or high reliability

A first pixel electrode is electrically connected to the transistor 5016 and a second pixel electrode is electrically connected to the transistor 5017. The first pixel electrode and the second pixel electrode are separated. Shapes of the first pixel electrode and the second pixel electrode are not especially limited. For example, the first pixel electrode may have a V-like shape.

A gate electrode of the transistor 5016 is electrically connected to the scan line 5012, and a gate electrode of the transistor 5017 is electrically connected to the scan line 5013. When different gate signals are supplied to the scan line 5012 and the scan line 5013, operation timings of the transistor 5016 and the transistor 5017 can be varied. As a result, alignment of liquid crystals can be controlled.

Furthermore, a capacitor may be formed using a capacitor line 5010, a gate insulator functioning as a dielectric, and a capacitor electrode electrically connected to the first pixel electrode or the second pixel electrode.

The multi-domain pixel includes a first liquid crystal element 5018 and a second liquid crystal element 5019 in one pixel. The first liquid crystal element 5018 includes the first pixel electrode, a counter electrode, and a liquid crystal layer therebetween. The second liquid crystal element 5019 includes the second pixel electrode, a counter electrode, and a liquid crystal layer therebetween.

Note that a pixel circuit in the display device of one embodiment of the present invention is not limited to that shown in FIG. 30B. For example, a switch, a resistor, a capacitor, a transistor, a sensor, a logic circuit, or the like may be added to the pixel circuit shown in FIG. 30B.

### [Organic EL Display Device]

FIG. 30C illustrates another example of a circuit configuration of the pixel. Here, a pixel structure of a display device using an organic EL element is shown.

In an organic EL element, by application of voltage to a light-emitting element, electrons are injected from one of a pair of electrodes included in the organic EL element and holes are injected from the other of the pair of electrodes, into a layer containing a light-emitting organic compound; thus, current flows. The electrons and holes are recombined, and thus, the light-emitting organic compound is excited. The light-emitting organic compound returns to a ground state from the excited state, thereby emitting light. Owing to such a mechanism, this light-emitting element is referred to as a current-excitation light-emitting element.

FIG. 30C illustrates an example of a pixel circuit. Here, one pixel includes two n-channel transistors. Note that any of the above-described transistors can be used as the n-channel transistors. Furthermore, digital time grayscale driving can be employed for the pixel circuit.

The configuration of the applicable pixel circuit and operation of a pixel employing digital time grayscale driving will be described.

A pixel 5020 includes a switching transistor 5021, a driver transistor 5022, a light-emitting element 5024, and a capacitor 5023. A gate electrode of the switching transistor 5021 is connected to a scan line 5026, a first electrode (one of a source electrode and a drain electrode) of the switching transistor 5021 is connected to a signal line 5025, and a second electrode (the other of the source electrode and the drain electrode) of the switching transistor 5021 is connected to a gate electrode of the driver transistor 5022. The gate electrode of the driver transistor 5022 is connected to a power supply line 5027 through the capacitor 5023, a first electrode of the driver transistor 5022 is connected to the power supply line 5027, and a second electrode of the driver transistor 5022 is connected to a first electrode (a pixel electrode) of the light-emitting element 5024. A second electrode of the light-emitting element 5024 corresponds to a common electrode 5028. The common electrode 5028 is electrically connected to a common potential line provided over the same substrate.

As each of the switching transistor 5021 and the driver transistor 5022, any of the above-described transistors can be used as appropriate. In this manner, an organic EL display device having high display quality and/or high reliability can be provided.

The potential of the second electrode (the common electrode 5028) of the light-emitting element 5024 is set to be a low power supply potential. Note that the low power supply potential is lower than a high power supply potential supplied to the power supply line 5027. For example, the low power supply potential can be GND, 0 V, or the like. The high power supply potential and the low power supply potential are set to be higher than or equal to the forward threshold voltage of the light-emitting element 5024, and the difference between the potentials is applied to the light-emitting element 5024, whereby current is supplied to the light-emitting element 5024, leading to light emission. The forward voltage of the light-emitting element 5024 refers to a voltage at which a desired luminance is obtained, and includes at least forward threshold voltage.

Note that gate capacitance of the driver transistor 5022 may be used as a substitute for the capacitor 5023 in some cases, so that the capacitor 5023 can be omitted. The gate capacitance of the driver transistor 5022 may be formed between the channel formation region and the gate electrode.

Next, a signal input to the driver transistor 5022 is described. In the case of a voltage-input voltage driving method, a video signal for turning on or off the driver transistor 5022 is input to the driver transistor 5022. In order for the driver transistor 5022 to operate in a linear region, voltage higher than the voltage of the power supply line 5027 is applied to the gate electrode of the driver transistor 5022. Note that voltage higher than or equal to voltage which is the sum of power supply line voltage and the threshold voltage Vₜₕ of the driver transistor 5022 is applied to the signal line 5025.

In the case of performing analog grayscale driving, a voltage higher than or equal to a voltage which is the sum of the forward voltage of the light-emitting element 5024 and the threshold voltage Vₜₕ of the driver transistor 5022 is applied to the gate electrode of the driver transistor 5022. A video signal by which the driver transistor 5022 is operated in a saturation region is input, so that current is supplied to the light-emitting element 5024. In order for the driver transistor 5022 to operate in a saturation region, the potential of the power supply line 5027 is set higher than the gate potential of the driver transistor 5022. When an analog video signal is used, it is possible to supply current to the light-emitting element 5024 in accordance with the video signal and perform analog grayscale driving.

Note that in the display device of one embodiment of the present invention, a pixel configuration is not limited to that shown in FIG. 30C. For example, a switch, a resistor, a capacitor, a sensor, a transistor, a logic circuit, or the like may be added to the pixel circuit shown in FIG. 30C.

In the case where any of the above-described transistors is used for the circuit shown in FIGS. 30A to 30C, the source electrode (the first electrode) is electrically connected to the low potential side and the drain electrode (the second electrode) is electrically connected to the high potential side. Furthermore, the potential of the first gate electrode may be controlled by a control circuit or the like and the potential described above as an example, e.g., a potential lower than the potential applied to the source electrode, may be input to the second gate electrode.

### <Electronic Device>

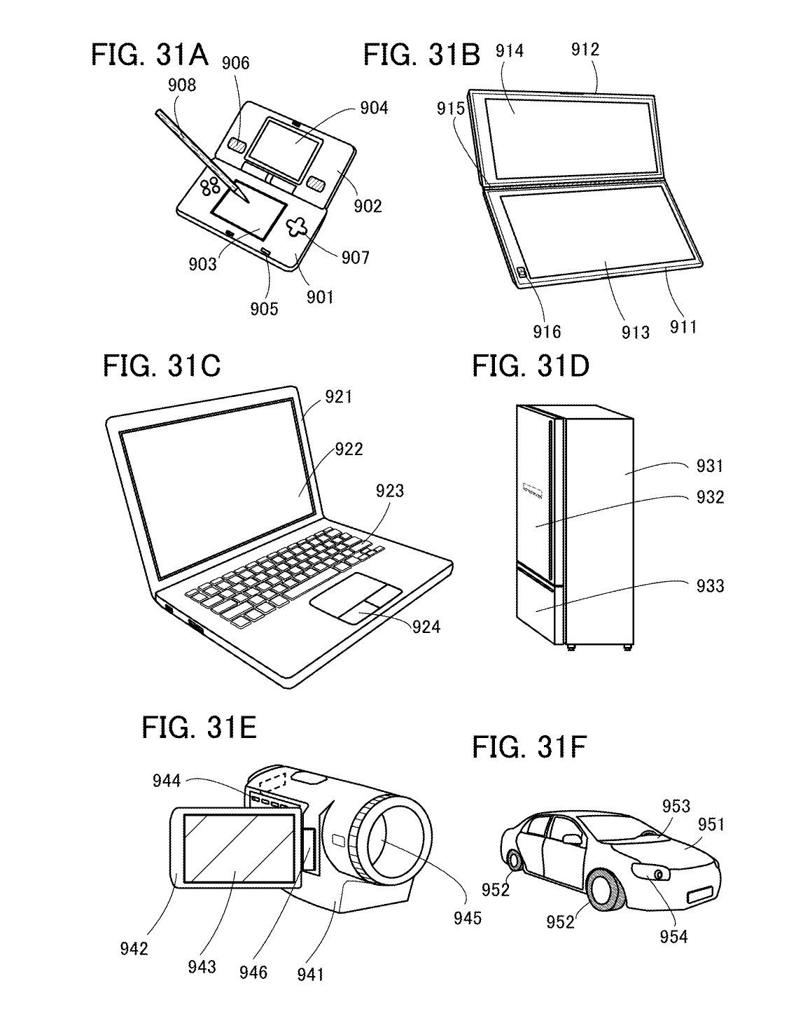

The semiconductor device of one embodiment of the present invention can be used for display devices, personal computers, or image reproducing devices provided with recording media (typically, devices which reproduce the content of recording media such as digital versatile discs (DVDs) and have displays for displaying the reproduced images). Other examples of electronic devices that can be equipped with the semiconductor device of one embodiment of the present invention are mobile phones, game machines including portable game consoles, portable data terminals, e-book readers, cameras such as video cameras and digital still cameras, goggle-type displays (head mounted displays), navigation systems, audio reproducing devices (e.g., car audio systems and digital audio players), copiers, facsimiles, printers, multifunction printers, automated teller machines (ATM), and vending machines. FIGS. 31A to 31F illustrate specific examples of these electronic devices.

FIG. 31A illustrates a portable game console including a housing 901, a housing 902, a display portion 903, a display portion 904, a microphone 905, a speaker 906, an operation key 907, a stylus 908, and the like. Although the portable game console in FIG. 31A has the two display portions 903 and 904, the number of display portions included in a portable game console is not limited to this.

FIG. 31B illustrates a portable data terminal including a first housing 911, a second housing 912, a first display portion 913, a second display portion 914, a joint 915, an operation key 916, and the like. The first display portion 913 is provided in the first housing 911, and the second display portion 914 is provided in the second housing 912. The first housing 911 and the second housing 912 are connected to each other with the joint 915, and the angle between the first housing 911 and the second housing 912 can be changed with the joint 915. An image on the first display portion 913 may be switched in accordance with the angle at the joint 915 between the first housing 911 and the second housing 912. A display device with a position input function may be used as at least one of the first display portion 913 and the second display portion 914. Note that the position input function can be added by providing a touch panel in a display device. Alternatively, the position input function can be added by providing a photoelectric conversion element called a photosensor in a pixel portion of a display device.

FIG. 31C illustrates a laptop personal computer, which includes a housing 921, a display portion 922, a keyboard 923, a pointing device 924, and the like.

FIG. 31D illustrates an electric refrigerator-freezer, which includes a housing 931, a door for a refrigerator 932, a door for a freezer 933, and the like.

FIG. 31E illustrates a video camera, which includes a first housing 941, a second housing 942, a display portion 943, operation keys 944, a lens 945, a joint 946, and the like. The operation keys 944 and the lens 945 are provided in the first housing 941, and the display portion 943 is provided in the second housing 942. The first housing 941 and the second housing 942 are connected to each other with the joint 946, and the angle between the first housing 941 and the second housing 942 can be changed with the joint 946. Images displayed on the display portion 943 may be switched in accordance with the angle at the joint 946 between the first housing 941 and the second housing 942.

FIG. 31F illustrates a car including a car body 951, wheels 952, a dashboard 953, lights 954, and the like.

### REFERENCE NUMERALS

400: substrate, 401: insulator, 402: insulator, 404: conductor, 406: semiconductor, 406a: semiconductor, 406b: semiconductor, 406c: semiconductor, 408: insulator, 410: conductor, 412: insulator, 414: conductor, 416: conductor, 416a: conductor, 416b: conductor, 436: semiconductor, 450: semiconductor substrate, 452: insulator, 454: conductor, 456: region, 460: region, 462: insulator, 464: insulator, 466: insulator, 468: insulator, 472a: region, 472b: region, 474a: conductor, 474b: conductor, 474c: conductor, 476a: conductor, 476b: conductor, 478a: conductor, 478b: conductor, 478c: conductor, 480a: conductor, 480b: conductor, 480c: conductor, 490: insulator, 492: insulator, 494: insulator, 496a: conductor, 496b: conductor, 496c: conductor, 498a: conductor, 498b: conductor, 500: substrate, 501: insulator, 502: insulator, 504: conductor, 506: semiconductor, 508: insulator, 510: conductor, 512: insulator, 516: conductor, 516a: conductor, 516b: conductor, 536: semiconductor, 600: substrate, 602: insulator, 604: conductor, 606: semiconductor, 608: insulator, 612: insulator, 616: conductor, 616a: conductor, 616b: conductor, 901: housing, 902: housing, 903: display portion, 904: display portion, 905: microphone, 906: speaker, 907: operation key, 908: stylus, 911: housing, 912: housing, 913: display portion, 914: display portion, 915: joint, 916: operation key, 921: housing, 922: display portion, 923: keyboard, 924: pointing device, 931: housing, 932: a door for a refrigerator, 933: a door for a freezer, 941: housing, 942: housing, 943: display portion, 944: operation key, 945: lens, 946: joint, 951: car body, 952: wheel, 953: dashboard, 954: light, 1189: ROM interface, 1190: substrate, 1191: ALU, 1192: ALU controller, 1193: instruction decoder, 1194: interrupt controller, 1195: timing controller, 1196: register, 1197: register controller, 1198: bus interface, 1199: ROM, 1200: memory element, 1201: circuit, 1202: circuit, 1203: switch, 1204: switch, 1206: logic element, 1207: capacitor, 1208: capacitor, 1209: transistor, 1210: transistor, 1213: transistor, 1214: transistor, 1220: circuit, 2100: transistor, 2200: transistor, 3001: wiring, 3002: wiring, 3003: wiring, 3004: wiring, 3005: wiring, 3200: transistor, 3300: transistor, 3400: capacitor, 5000: substrate, 5001: pixel portion, 5002: scan line driver circuit, 5003: scan line driver circuit, 5004: signal line driver circuit, 5010: capacitor line, 5012: scan line, 5013: scan line, 5014: signal line, 5016: transistor, 5017: transistor, 5018: liquid crystal element, 5019: liquid crystal element, 5020: pixel, 5021: switching transistor, 5022: driver transistor, 5023: capacitor, 5024: light-emitting element, 5025: signal line, 5026: scan line, 5027: power supply line, 5028: common electrode, 5100: pellet, 5120: substrate, and 5161: region.

This application is based on Japanese Patent Application serial no. 2014-108709 filed with Japan Patent Office on May 27, 2014, the entire contents of which are hereby incorporated by reference.

1. A semiconductor device comprising:
an insulator;
a first conductor;
a second conductor;
a third conductor; and
a semiconductor being island-shaped,
wherein the first conductor comprises a region in contact with a top surface of the semiconductor,
wherein the first conductor does not comprise a region in contact with any side surface of the semiconductor,
wherein the second conductor comprises a region in contact with the top surface of the semiconductor,
wherein the second conductor does not comprise a region in contact with any side surface of the semiconductor,
wherein the third conductor comprises a region in which the semiconductor and the third conductor overlap with each other with the insulator positioned therebetween,
wherein the first conductor comprises a first side surface, a second side surface, and a third side surface,
wherein the second conductor comprises a fourth side surface,
wherein the first conductor and the second conductor are positioned to make the first side surface and the fourth side surface face each other,
wherein the first conductor comprises a first corner portion between the first side surface and the second side surface and a second corner portion between the second side surface and the third side surface, and
wherein the first corner portion comprises a portion having a smaller radius of curvature than the second corner portion.

2. A semiconductor device comprising:
a first insulator;
a second insulator;
a first conductor;
a second conductor;
a third conductor;
a fourth conductor; and
a semiconductor,
wherein the semiconductor comprises a region in contact with a top surface of the first insulator,
wherein the first conductor comprises a region in contact with a top surface of the semiconductor,
wherein the second conductor comprises a region in contact with the top surface of the semiconductor,
wherein the second insulator comprises a region in contact with the top surface of the semiconductor,
wherein the third conductor comprises a region in which the semiconductor and the third conductor overlap with each other with the second insulator positioned therebetween,
wherein an opening reaching the fourth conductor is provided in the semiconductor and the first insulator, and
wherein the first conductor comprises a region in contact with the fourth conductor through the opening.

3. The semiconductor device according to claim 1, wherein the semiconductor comprises a region in which a length in a short-side direction is more than or equal to 5 nm and less than or equal to 300 nm.

4. The semiconductor device according to claim 1,
wherein the semiconductor is an oxide comprising indium, an element M, and zinc, and
wherein the element M is one of aluminum, gallium, yttrium, and tin.

5. The semiconductor device according to claim 1,
wherein the semiconductor comprises a first semiconductor and a second semiconductor, and
wherein the first semiconductor has higher electron affinity than the second semiconductor.

6. The semiconductor device according to claim 2, wherein the semiconductor comprises a region in which a length in a short-side direction is more than or equal to 5 nm and less than or equal to 300 nm.

7. The semiconductor device according to claim 2,
wherein the semiconductor is an oxide comprising indium, an element M, and zinc, and
wherein the element M is one of aluminum, gallium, yttrium, and tin.

8. The semiconductor device according to claim 2,
wherein the semiconductor comprises a first semiconductor and a second semiconductor, and
wherein the first semiconductor has higher electron affinity than the second semiconductor.

9. A method for manufacturing a semiconductor device, comprising the steps of:
depositing a first semiconductor;
depositing a first conductor over the first semiconductor;
etching a portion of the first conductor to form a second conductor and to expose a portion of the first semiconductor;
forming a resist over a portion of the second conductor and a portion of the exposed portion of the first semiconductor;
etching the second conductor with the resist used as a mask to form a third conductor and a fourth conductor; and
etching the first semiconductor with the resist, the third conductor, and the fourth conductor used as masks to form a second semiconductor.

10. The method for manufacturing the semiconductor device according to claim 9, wherein the second semiconductor comprises a region in which a length in a short-side direction is more than or equal to 5 nm and less than or equal to 300 nm.

11. A method for manufacturing a semiconductor device, comprising the steps of:
depositing a first semiconductor;
etching a portion of the first semiconductor to form a second semiconductor;
depositing a first conductor over the second semiconductor;
etching a portion of the first conductor to form a second conductor and to expose a portion of the second semiconductor;
forming a resist over a portion of the second conductor and the exposed portion of the second semiconductor;
etching the second conductor with the resist used as a mask to form a third conductor and a fourth conductor; and
etching the second semiconductor with the resist, the third conductor, and the fourth conductor used as masks to form a third semiconductor.

12. The method for manufacturing the semiconductor device according to claim 11, wherein the third semiconductor comprises a region in which a length in a short-side direction is more than or equal to 5 nm and less than or equal to 300 nm.

13. The method for manufacturing the semiconductor device according to claim 9,
wherein the first semiconductor is an oxide comprising indium, an element M, and zinc, and
wherein the element M is one of aluminum, gallium, yttrium, and tin.

14. The method for manufacturing the semiconductor device according to claim 11,
wherein the first semiconductor is an oxide comprising indium, an element M, and zinc, and
wherein the element M is one of aluminum, gallium, yttrium, and tin.
